(19) United States
(12) Patent Application Publication
(10) Pub. No.: US 2026/0216928 A1
(43) Pub. Date: Jul. 30, 2026

(54) MOLD RELEASE FILM

(71) Applicant: SUMITOMO BAKELITE CO., LTD., Tokyo (JP)

(72) Inventor: Shinichi Maesowa, Shinagawa-ku, Tokyo (JP)

(73) Assignee: SUMITOMO BAKELITE CO., LTD., Tokyo (JP)

(21) Appl. No.: 18/726,632

(22) PCT Filed: Dec. 27, 2022
(86) PCT No.: PCT/JP2022/048384

§ 371 Date: Jul. 3, 2024

(30) Foreign Application Priority Data
Jan. 7, 2022 (JP) 2022-001549
Jan. 7, 2022 (JP) 2022-001551
Oct. 26, 2022 (JP) 2022-171349
Nov. 22, 2022 (JP) 2022-186862

(51) Int. Cl. B29C 33/68; C09D 133/04; C09D 167/02; C09D 179/02

(52) U.S. Cl. CPC B29C 33/68; C09D 133/04; C09D 167/02; C09D 179/02

(57) ABSTRACT

A mold release film (100) of the present invention has a configuration in which a first mold release layer (11) constituting one mold release surface, an interlayer (20), and a second mold release layer (12) constituting the other mold release surface are laminated in this order, in which the interlayer (20) is composed of a resin composition for the interlayer, containing a polyester resin.

### TECHNICAL FIELD

The present invention relates to a mold release film.

### BACKGROUND ART

A mold release film has been used in a case of manufacturing a molded product or in a case of manufacturing a laminate formed by laminating different materials together.

For example, in a case of manufacturing a flexible printed circuit board (hereinafter, also referred to as “FPC”) in which a coverlay film (hereinafter, also referred to as “CL film”) is attached to a flexible film in which a circuit is exposed (hereinafter, also referred to as “circuit-exposed film”) through an adhesive by heating press, the mold release film is disposed between the coverlay film and a hot plate and is heated and pressed together with the hot plate (for example, Patent Document 1).

In addition, for example, in a manufacturing process of a semiconductor device, it is known that a semiconductor device is manufactured by disposing the mold release film between a mold and a molding target, and sealing the molding target on which an electronic component such as a semiconductor element is mounted with a resin by a molding method such as a transfer mold forming method and a compression mold forming method (for example, Patent Documents 2 to 4).

### RELATED DOCUMENT

### Patent Document

[Patent Document 1] Japanese Unexamined Patent Publication No. 2015-58691
[Patent Document 2] Japanese Unexamined Patent Publication No. 2020-151949
[Patent Document 3] Japanese Unexamined Patent Publication No. 2020-19264
[Patent Document 4] Japanese Unexamined Patent Publication No. 2016-092272

### SUMMARY OF THE INVENTION

### Technical Problem

In the related art, the mold release film is required to have mold releasability for easily releasing a molded product obtained after the heating press, and development for obtaining higher mold releasability has been studied.

However, in recent years, automation of the manufacturing process of the molded product has progressed, and there has been a case in which the mold release film peeled off from the molded product after the heating press is attached to the mold on the opposite side or the hot plate side. Therefore, the present inventor has focused on a new problem of suppressing sticking to a hot plate side while obtaining favorable mold releasability with respect to a molded product.

Furthermore, in a case where the molded product obtained from the mold release film in the related art is used, there is a problem that wrinkles or distortion generated in the mold release film are transferred to the surface of the molded product, or adhesiveness is lowered due to curling of an end part of the mold release film during thermal pressing, and there is room for improvement in terms of suppressing the curling of the mold release film while obtaining a molded product having a more favorable appearance.

### Solution to Problem

The present inventor has conducted studies to solve the above-described problem, and has found that it is effective to use a polyester resin in an interlayer to control thermal deformation of the mold release film during the heating press, thereby completing a first aspect of the invention.

In addition, the present inventor has found that it is effective to control a surface free energy of both surfaces of the mold release film, thereby completing a second aspect of the present invention.

Furthermore, the present inventor has studied a cause of wrinkles or curls occurring in the mold release film, and has found the following problems.

In general, in a case where the mold release film is used, the mold release film is first deformed to be along an inner surface shape of a cavity concave portion of a lower mold so as to be closely adhered to the inner surface of the lower mold. Next, a sealing resin material is filled in the cavity concave portion of the lower mold on which the mold release film is disposed, and a molding target held by an upper mold is clamped from upper and lower directions to be compression-molded, thereby resin-sealing the molding target. Here, in such a compression molding, since a bottom surface of the lower mold is gradually pushed up to reduce the volume of the concave portion, surplus is generated in the mold release film disposed along the inner surface shape of the concave portion.

In the related art, it has been known that the mold release film has a property of gradually contracting (elastically recovering) by heating. However, the present inventor has newly found that, in a case where a balance of elastic recovery between a TD direction and an MD direction of the mold release film is lost, wrinkles or curls are likely to occur in the mold release film. As a result of further detailed studies, it has been found that, in order to suppress the occurrence of wrinkles or curls as described above, it is effective to devise a new index for a thermal dimensional change rate of the mold release film and to control such an index, thereby completing a third aspect of the invention.

According to the present invention, there is provided a mold release film including a first mold release layer constituting one mold release surface, an interlayer, and a second mold release layer constituting the other mold release surface, in which the first mold release layer, the interlayer, and the second mold release layer are laminated in this order, and in which the interlayer is composed of a resin composition for the interlayer, containing a polyester resin (first aspect of the invention).

According to the present invention, there is provided a mold release film including a first mold release layer on at least one surface, in which, in a case where a surface free energy of the one surface of the mold release film is denoted by SC1 and a surface free energy of the other surface of the mold release film is denoted by SC2, SC1 is 15 to 35 [mJ/m²] and |SC1-SC2| is less than 2.0 (second aspect of the present invention).

According to the present invention, there is provided a mold release film including a first resin layer as a mold release surface and a second resin layer formed of a resin composition different from the first resin layer, in which the first resin layer and the second resin layer are laminated, and in which, in a case where a thermal dimensional change rate is measured according to the following procedure a, a thermal dimensional change rate At of the mold release film at 180° C. in a width direction (TD) is equal to or less than 2.5%, and a difference between a thermal dimensional change rate Am of the mold release film at 180° C. in a length direction (MD) and the thermal dimensional change rate At of the mold release film at 180° C. in the width direction (TD) is equal to or less than 5.0% (third aspect of the present invention).

Procedure a: using a thermo-mechanical analyzer, a thermal dimensional change rate of the mold release film is measured by heating the mold release film from 20° C. to 210° C. at a temperature rising rate of 5° C./min in a state in which a load of 10 mN is applied to the mold release film.

### Advantageous Effects of Invention

According to the present invention, there are provided a mold release film capable of obtaining favorable mold releasability with respect to a molded product and capable of suppressing sticking to a hot plate side, and a mold release film capable of suppressing occurrence of wrinkles and curls.

### BRIEF DESCRIPTION OF THE DRAWINGS

FIG. 1 is a cross-sectional view schematically showing a cross section of a mold release film according to a first embodiment.

FIG. 2 is a cross-sectional view schematically showing a modification example of the mold release film according to first embodiment.

FIG. 3 is a schematic cross-sectional view of a cross section of a mold release film according to a second embodiment.

FIG. 4 is a cross-sectional view schematically showing a cross section of a mold release film according to a third embodiment.

FIG. 5 is a diagram showing a TMA measurement result of the mold release film according to the third embodiment by a procedure a of Example 1.

FIG. 6 is a diagram showing a TMA measurement result of the mold release film according to the third embodiment by a procedure b of Example 1.

### DESCRIPTION OF EMBODIMENTS

Hereinafter, embodiments of the present invention will be described in detail with reference to the drawings. The drawings are merely for explanation. The shape, the aspect ratio, and the like of each member in the drawings are not always corresponding to the real object.

Unless otherwise specified, the expression “a to b” in the description of the numerical range in the present specification means equal to or more than a and equal to or less than b. For example, “1% to 5% by mass” means “equal to or more than 1% by mass and equal to or less than 5% by mass”.

In the present specification, an MD direction represents Machine Direction and means a flow direction of a resin, and a TD direction represents Transverse Direction and means a vertical direction.

Each component and material exemplified in the present specification may be used alone or in combination of two or more kinds thereof, unless otherwise specified.

### 1. First Embodiment

### <Mold Release Film>

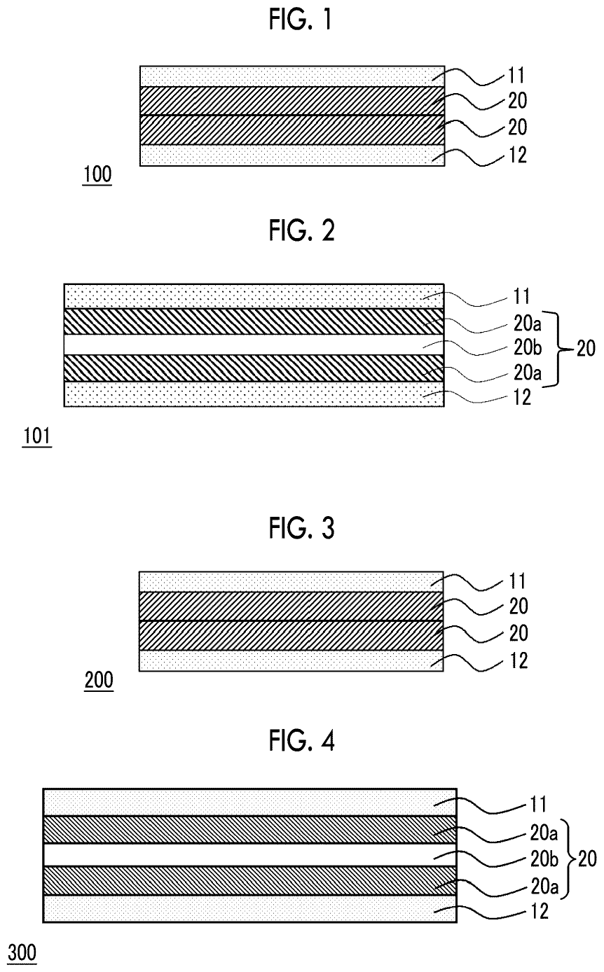

FIG. 1 is a cross-sectional view schematically showing a cross section of a mold release film according to a first embodiment.

As shown in FIG. 1, a mold release film 100 according to the first embodiment has a configuration in which a first mold release layer 11 constituting one mold release surface, an interlayer 20, and a second mold release layer 12 constituting the other mold release surface are laminated in this order. In the first embodiment, the interlayer 20 has a two-layer structure.

In the mold release film 100, in a case where the interlayer 20 is composed of a resin composition for the interlayer, containing a polyester resin, it is possible to suppress thermal deformation during heating press and to suppress the fact that the mold release film 100 is too soft and is unlikely to adhere to and peel off from a mold.

### (Symmetry)

It is preferable that the mold release film 100 has a symmetrical structure and/or a symmetrical composition with respect to a center plane in a direction perpendicular to a thickness direction of the mold release film. As a result, it is possible to further suppress the occurrence of the curls at an end part of the mold release film 100 while suppressing sticking property. As a result, it is possible to reduce the fact that a curl portion is folded and non-air-tight adhesiveness is lowered during non-air-tight adhesion of the mold release film 100 to the mold, and thus the mold release film 100 is not appropriately used and appearance of the molded product is deteriorated.

The symmetric structure means that, in a case where the mold release film 100 is divided into two in upper and lower directions with the center plane in the direction perpendicular to the thickness direction as a reference, the structures such as the thicknesses of the upper layer and the lower layer, the surface roughness of the mold release surface, and the layer configuration are the same. In the first embodiment, the center plane in the direction perpendicular to the thickness direction of the mold release film 100 is an interface between two interlayers 20. Since the thicknesses of the first mold release layer 11 and the second mold release layer 12, the surface roughness of each mold release surface, and the layer configuration of the mold release film 100 are the same, the mold release film 100 has a symmetrical structure.

Examples of the surface roughness include a maximum height Rz and an arithmetic mean roughness Ra, measured according to JIS B 0601:2013. In addition, in the first embodiment, the “structures are the same” is not limited to a case where measured values are completely matched, and includes a measurement error and a minute difference generated in manufacturing.

The symmetrical composition means that, in a case where the mold release film 100 is divided into two in upper and lower directions with the center plane in the direction perpendicular to the thickness direction as a reference, the layer configurations constituting the upper layer and the lower layer are the same, and each layer is composed of the same material.

In the first embodiment, in a case where the mold release film 100 is divided into two in upper and lower directions with the center plane in the direction perpendicular to the thickness direction as a reference, the upper layer includes the first mold release layer 11 and the interlayer 20, and the lower layer includes the second mold release layer 12 and the interlayer 20. In the first embodiment, it is preferable that the first mold release layer 11 and the second mold release layer 12 are composed of the same material.

In the case of the symmetrical composition, for example, the thicknesses of the upper layer and the lower layer of the mold release film 100 may be different from each other, and the surface roughness of the mold release surfaces may be different from each other.

### (Thickness)

A thickness of the mold release film 100 is preferably equal to or more than 5 μm and equal to or less than 150 μm, more preferably equal to or more than 10 μm and equal to or less than 100 μm, still more preferably equal to or more than 15 μm and equal to or less than 80 μm, and particularly preferably equal to or more than 20 μm and 75 μm.

### (Tensile Stress)

In the mold release film 100 according to the first embodiment, a tensile stress of the mold release film 100 in the MD direction, which is obtained in a case where a tensile test is performed according to JIS X 7127 under conditions of 180° C. and a load rate of 500 mm/min, is preferably equal to or more than 40 MPa, more preferably equal to or more than 50 MPa, and still more preferably equal to or more than 60 MPa.

By setting the tensile stress to be equal to or more than the above-described lower limit value, even in a case where a tension is applied to the mold release film 100 during transportation, during unwinding, during roll storage, or the like, an appropriate stiffness of the mold release film 100 is maintained, and the thermal deformation of the mold release film 100 during the heating press is suppressed, so that the sticking property to the mold can be easily suppressed. In addition, the curling of the end part of the mold release film 100 according to the first embodiment can be reduced, and the mold release film 100 can be satisfactorily subjected to vacuum suction without the end part being folded during the vacuum suction.

The tensile stress of the mold release film 100 according to the first embodiment can be realized, for example, by selecting and combining known methods such as the type of raw materials and the film forming method of the first mold release layer 11 and the second mold release layer 12, the type of raw materials and the film forming method of the interlayer 20, the control of the surface roughness of the mold release film 100, and the method for manufacturing the mold release film 100, and by using a method different from the related art.

For example, in a case where the film is formed by a film forming method of stretching the film, a film having a hardness and a stiffness can be formed as compared with a non-stretched film. In addition, as an example of the method for manufacturing the mold release film 100 according to the first embodiment, in a roll-to-roll method, a coating liquid of a resin composition for a mold release layer, which constitutes the first mold release layer 11 or the second mold release layer 12, may be applied onto one surface of the interlayer 20. In this case, in a case where a transport tension of the film is too high, excessive stress is applied to the first mold release layer 11 or the second mold release layer 12. Therefore, by setting the transport tension of the roll in the roll-to-roll method to be equal to or less than 100 N, the stress applied to the first mold release layer 11 or the second mold release layer 12 can be reduced, and the desired mold release film 100 can be obtained.

Hereinafter, each layer included in the mold release film 100 according to the first embodiment will be described in detail.

### [First Mold Release Layer 11]

The first mold release layer 11 in the first embodiment forms one surface of the mold release film 100, and in a case where the mold release film 100 is disposed on the mold, the first mold release layer 11 is a resin layer constituting a surface on a side in contact with a molded product later.

A thickness of the first mold release layer 11 is preferably 0.01 to 50 μm, more preferably 0.05 to 30 μm, still more preferably 0.08 to 25 μm, and particularly preferably 0.1 to 15 μm.

By setting the thickness of the first mold release layer 11 to be equal to or more than the above-described lower limit value, it is possible to impart mold releasability required for the mold release film 100. On the other hand, by setting the thickness of the first mold release layer 11 to be equal to or less than the above-described upper limit value, the rigidity of the mold release film 100 can be controlled, and the balance between the suppression of adhesion and the mold releasability can be improved.

In addition, from the viewpoint of mold releasability and appearance of the molded product, a surface roughness Ra of the surface of the mold release film 100 on the first mold release layer 11 side is preferably 0.01 to 4 μm, more preferably 0.05 to 3 μm, and still more preferably 0.1 to 2 μm.

By setting the surface roughness Ra to be equal to or more than the above-described lower limit value, the mold releasability during molding can be improved. On the other hand, by setting the surface roughness Ra to be equal to or less than the above-described upper limit value, the balance between the mold releasability and favorable appearance of the molded product can be improved.

As a control method of the surface roughness of the surface on the first mold release layer 11 side, the surface roughness can be adjusted by a known method such as transferring the film with an embossed pattern using a roll subjected to an embossing process in the manufacturing step of the mold release film, or blending particles into the material constituting the first mold release layer 11.

The surface roughness Ra of the first mold release layer 11 is measured according to JIS B 0601:2013.

In the first embodiment, the first mold release layer 11 is composed of a first resin composition which is a resin composition for forming a mold release layer.

In addition, the first mold release layer 11 is a stretched or non-stretched film formed of the first resin composition. Whether the film is stretched or unstretched can be appropriately set, but it is preferable that the film is a stretched film in a case of improving the rigidity of the film, and the film is a non-stretched film in a case of improving the moldability. In addition, the stretching can be obtained by using a known method such as sequential biaxial stretching, simultaneous biaxial stretching, and tubular stretching.

Hereinafter, the first resin composition will be described in detail.

The first mold release layer 11 contains, as a resin, one kind or two or more kinds selected from a silicone resin, a fluororesin, a melamine resin, an epoxy resin, a phenol resin, and an acrylic resin. Among these, from the viewpoint of obtaining a molded product having a favorable appearance and improving workability of the mold release film 100, it is preferable to contain one kind or two or more kinds selected from a silicone resin, a melamine resin, and an acrylic resin, and it is more preferable to contain a melamine resin or an acrylic resin.

### (Silicone Resin)

The silicone resin is not particularly limited. For example, polysiloxane including two or more siloxane bonds (—Si—O—), such as known or commercially available various siloxane-based polymers, can be used.

The polysiloxane preferably includes one kind or two kinds selected from polyorganosilsesquioxane (so-called a ladder silicone), a ladder silicone-modified acrylic polymer, vinyl group-containing organopolysiloxane, and organohydrogen polysiloxane.

Among these, a ladder silicone or a ladder silicone-modified acrylic polymer is preferable. The ladder silicone and the ladder silicone-modified acrylic polymer are polysiloxanes having at least an SiO3/2 (T) unit and having a ladder-type molecular skeletal structure. As a result, since free rotation of the siloxane bond is constrained, heat resistance or mold releasability can be obtained.

The ladder silicone is a polysiloxane having a ladder-type organopolysiloxane structure. Specifically, the ladder silicone is a polysiloxane having a constitutional unit represented by Formula (1).

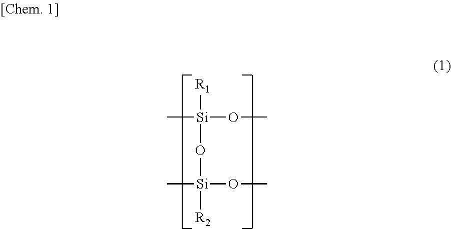

In Formula (1), R₁ and R₃ each independently represent an alkyl group having 1 to 3 carbon atoms or a substituted or unsubstituted phenyl group.

The ladder silicone-modified acrylic polymer is an acrylic polymer into which the above-described ladder-type organopolysiloxane structure is introduced. Specifically, the ladder silicone-modified acrylic polymer is an acrylic polymer having a constitutional unit represented by Formula (2).

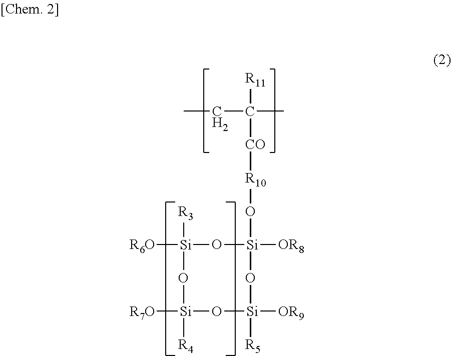

In Formula (2), R₃ to R₅ each independently represent an alkyl group having 1 to 3 carbon atoms or a substituted or unsubstituted phenyl group, R₆ to R₉ each independently represent a hydrogen atom, an alkyl group having 1 to 3 carbon atoms, or a trialkylsilyl group having 1 to 3 carbon atoms, R₁₀ represents an alkylene group having 1 to 6 carbon atoms, and R₁₁ represents a hydrogen atom or an alkyl group having 1 to 3 carbon atoms.

Among these, R₆ to R₉ are each independently preferably a trimethylsilyl group, and R₁₁ is preferably a hydrogen atom.

The acrylic skeleton in the ladder silicone-modified acrylic polymer preferably has a constitutional unit represented by Formula (3).

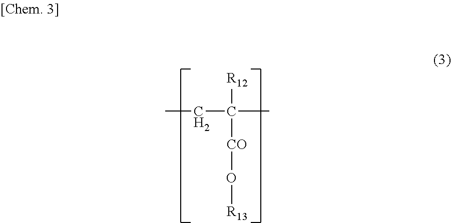

In Formula (3), R₁₂ represents an alkyl group having 1 to 3 carbon atoms, and R₁₃ represents a hydrogen atom, an alkyl group having 1 to 10 carbon atoms, or an alkoxy group having 1 to 10 carbon atoms.

Among these, R₁₂ is preferably a methyl group.

Specific examples of the ladder silicone-modified acrylic polymer include ladder silicone-modified acrylic polymers (trade name: SQ100 and SQ200, manufactured by Tokushiki Co., Ltd.).

### (Fluororesin)

Specific examples of the above-described fluorine-based resin include polymers of a monomer such as tetrafluoroethylene, hexafluoropropylene, chlorotrifluoroethylene, vinylidene fluoride, vinyl fluoride, and perfluoroalkyl vinyl ether, and copolymers of two or more kinds of the monomers. These may be used alone or in combination of two or more thereof.

### (Melamine Resin)

The above-described melamine resin is obtained, for example, by polycondensing a melamine compound and formaldehyde under a neutral or weakly alkaline condition. Specific examples thereof include an alkylated melamine resin such as a methylated melamine resin and a butylated melamine resin, a methylolated melamine resin, and an alkyl etherified melamine.

Among these, a methylated melamine resin including a constitutional unit derived from methylated melamine is preferable. The methylated melamine resin has at least one methoxymethyl group (—CH₂OCH₃), and an average degree of polymerization thereof is 1.1 to 10.

### (Epoxy Resin)

As the above-described epoxy resin, regardless of the molecular weight and molecular structure, a monomer, an oligomer, or a polymer having two or more epoxy groups in one molecule can be used. Specific examples of such an epoxy resin include one kind or two or more kinds selected from bisphenol-based epoxy resins such as a bisphenol A-type epoxy resin, a bisphenol F-type epoxy resin, a bisphenol E-type epoxy resin, a bisphenol S-type epoxy resin, a hydrogenated bisphenol A-type epoxy resin, a bisphenol M-type epoxy resin (4,4′-(1,3-phenylenediisopropylene) bisphenol-type epoxy resin), a bisphenol P-type epoxy resin (4,4)-(1,4-phenylenediisopropylene)bisphenol-type epoxy resin), a bisphenol Z-type epoxy resin (4,4′-cyclohexylidenebisphenol-type epoxy resin); novolac-type epoxy resins such as a phenol novolac-type epoxy resin, a brominated phenol novolac-type epoxy resin, a cresol novolac-type epoxy resin, a tetraphenyl group ethane novolac-type epoxy resin, and a novolac-type epoxy resin having a condensed aromatic hydrocarbon structure; biphenyl-type epoxy resins; aralkyl-type epoxy resins such as a xylylene-type epoxy resin and a biphenyl aralkyl-type epoxy resin; epoxy resins having a naphthalene skeleton, such as a naphthylene ether-type epoxy resin, a naphthol-type epoxy resin, a naphthalene-type epoxy resin, a naphthalenediol-type epoxy resin, a bifunctional to tetrafunctional epoxy-type naphthalene resin, a binaphthyl-type epoxy resin, and a naphthalene aralkyl-type epoxy resin; anthracene-type epoxy resins; phenoxy-type epoxy resins; dicyclopentadiene-type epoxy resins; norbornene-type epoxy resins; adamantane-type epoxy resins; heterocyclic epoxy resins such as a fluorene-type epoxy resin, a phosphorus-containing epoxy resin, an alicyclic epoxy resin, an aliphatic chain-like epoxy resin, a bisphenol A novolac-type epoxy resin, a bixylenol-type epoxy resin, a triphenol methane-type epoxy resin, a trihydroxyphenylmethane-type epoxy resin, a tetraphenylol ethane-type epoxy resin, and a triglycidyl isocyanurate; glycidylamines such as N,N,N′,N′-tetraglycidylmetaxylenediamine, N, N,N′, N′-tetraglycidylbisaminomethylcyclohexane, and N, N-diglycidylaniline; or a copolymer of glycidyl (meth)acrylate and a compound having an ethylenically unsaturated double bond, an epoxy resin having a butadiene structure, a diglycidyl etherified product of bisphenol, a diglycidyl etherified product of naphthalenediol, and a glycidyl etherified product of phenols.

### (Phenol Resin)

The above-described phenol resin can include one kind or two or more kinds selected from novolac-type phenol resins such as a phenol novolac resin, a cresol novolac resin, a tert-butylphenol novolac resin, and a nonylphenol novolac resin; phenol aralkyl resins such as a phenylene skeleton-containing phenol aralkyl resin and a biphenylene skeleton-containing phenol aralkyl resin; and phenol resins having a condensed polycyclic structure such as a naphthalene skeleton and an anthracene skeleton.

### (Acrylic Resin)

Specific examples of the acrylic resin include resins composed of a monomer such as an acrylic acid ester, for example, acrylic acid, methacrylic acid, methyl acrylate, ethyl acrylate, butyl acrylate, and 2-ethylhexyl acrylate; a methacrylic acid ester, for example, methyl methacrylate, ethyl methacrylate, and butyl methacrylate; and acrylonitrile, methacrylonitrile, or acrylamide. The acrylic resin includes one or two or more monomers of these examples as a constitutional monomer. In addition, the acrylic resin may further include a monomer other than these examples as a constitutional monomer. In addition, these monomers may be derivatives of the monomers.

The first resin composition may contain other components in addition to the above-described resins, as long as the characteristics of the mold release film 100 are not impaired. The other components are not limited, and particles, a coupling agent, an acid catalyst, a solvent, an antistatic agent, a leveling agent, a dispersing agent, a pigment, a dye, an antioxidant, a flame retardant, a thermal conductivity improver, and the like can be appropriately blended. Hereinafter, the representative components will be described.

### (Particles)

The first resin composition may contain particles. As a result, the surface roughness of the mold release film 100 can be easily controlled regardless of the film forming method of the first mold release layer 11. That is, in a case where the first mold release layer 11 is the stretched film, it is difficult to perform the embossing on the surface of the mold release film 100 on the first mold release layer 11 side, but by containing the particles in the first mold release layer 11, the surface roughness can be controlled regardless of whether the first mold release layer 11 is the stretched film or the non-stretched film. In addition, the surface of the mold release film 100 on the first mold release layer 11 side can be easily roughened by the particle size and the content of the particles as compared with a case of attempting to roughen the surface.

Examples of the particles contained in the first resin composition include one kind or two or more kinds of organic particles and/or inorganic particles selected from the group consisting of a melamine resin, a polystyrene resin, an acrylic resin, a polyimide resin, a polyester resin, a silicone resin, a polypropylene resin, a polyethylene resin, and a fluororesin. The first mold release layer 11 in the first embodiment may contain one kind or two or more kinds of these particles.

Examples of the above-described inorganic particles include silicates such as talc, calcined clay, uncalcined clay, mica, and glass; oxides such as titanium oxide, alumina, boehmite, and silica; carbonates such as calcium carbonate, magnesium carbonate, and hydrotalcite; hydroxides such as aluminum hydroxide, magnesium hydroxide, and calcium hydroxide; sulfates or bisulfates, such as barium sulfate, calcium sulfate, and calcium bisulfate; borates such as lead metaborate, barium metaborate, aluminum borate, calcium borate, and sodium borate; nitrides such as aluminum nitride, boron nitride, silicon nitride, and carbon nitride; and titanates such as strontium titanate and barium titanate. These may be used alone or in combination of two or more kinds thereof.

From the viewpoint of improving adhesiveness to the first mold release layer 11, the inorganic particles may be subjected to a surface treatment. The surface treatment is appropriately selected according to the organic material constituting the first mold release layer 11, and in a case where the first mold release layer 11 contains a melamine resin, examples thereof include a coupling agent having a functional group such as amine, epoxy, and isocyanate. The coupling agent will be described later.

A content of the particles contained in the first mold release layer 11 is preferably 10% to 50% by mass, more preferably 15% to 45% by mass, and still more preferably 20% to 40% by mass with respect to the total amount of the first mold release layer 11.

By setting the content of the particles to be equal to or more than the above-described lower limit value, the surface roughness of the surface can be increased, and favorable mold releasability and handleability can be obtained.

On the other hand, by setting the content of the particles to be equal to or less than the above-described upper limit value, film-forming properties can be favorably maintained.

In a case where gloss is imparted to the molded product obtained from the mold release film 100, the content of the particles may be 0% by mass.

### (Silane Coupling Agent)

The silane coupling agent can have a hydrolyzable group. The hydrolyzable group is hydrolyzed by water to form a hydroxyl group, and this hydroxyl group reacts with a hydroxyl group on the surface of the inorganic particles to modify the surface of the inorganic particles.

In addition, the silane coupling agent can include a silane coupling agent having a reactive group such as a vinyl group, an epoxy group, an isocyanate group, and an amino group. As a result, the inorganic particles surface-modified with the silane coupling agent can react with the resin in the first mold release layer 11, and as a result, the inorganic particles can be prevented from falling off from the first mold release layer 11.

### (Solvent)

The first resin composition may contain a solvent, for example, according to the method for manufacturing the first mold release layer 11. In a case of containing a solvent, the first resin composition can be dissolved in the solvent and coated to manufacture the first mold release layer 11.

The solvent is not particularly limited, and specific examples thereof include water; aliphatic hydrocarbons such as pentane, hexane, cyclohexane, heptane, methylcyclohexane, ethylcyclohexane, octane, decane, dodecane, and tetradecane; aromatic hydrocarbons such as benzene, toluene, ethylbenzene, xylene, trifluoromethylbenzene, and benzotriphloride; ethers such as diethyl ether, diisopropyl ether, dibutyl ether, cyclopentylmethyl ether, cyclopentylethyl ether, ethylene glycol dimethyl ether, ethylene glycol diethyl ether, diethylene glycol dimethyl ether, 1,4-dioxane, 1,3-dioxane, and tetrahydrofuran; haloalkanes such as dichloromethane, chloroform, 1,1-dichloroethane, 1,2-dichloroethane, 1,1,1-trichloroethane, and 1,1,2-trichloroethane; carboxylic acid amides such as N, N-dimethylformamide and N, N-dimethylacetamide; sulfoxides such as dimethyl sulfoxide and diethyl sulfoxide; and alcohols such as ethanol and isopropyl alcohol. These may be used alone or in combination of two or more thereof.

### [Second Mold Release Layer 12]

The second mold release layer 12 in the first embodiment forms the other surface of the mold release film 100, and in a case where the mold release film 100 is disposed on the mold, the second mold release layer 12 is a resin layer constituting a surface on a side in contact with the mold.

A thickness of the second mold release layer 12 is preferably 0.01 to 50 μm, more preferably 0.05 to 30 μm, still more preferably 0.08 to 25 μm, and still more preferably 0.1 to 15 μm.

By setting the thickness of the second mold release layer 12 to be equal to or more than the above-described lower limit value, the rigidity can be increased and the sticking property can be improved. On the other hand, by setting the thickness of the second mold release layer 12 to be equal to or less than the above-described upper limit value, the flexibility of the mold release film 100 is improved, and favorable mold followability is easily obtained.

The thickness of the second mold release layer 12 may be the same as or different from that of the first mold release layer 11, but from the viewpoint of suppressing curling, it is preferable to be the same.

In addition, from the viewpoint of mold releasability and appearance of the molded product, a surface roughness Ra of the surface of the mold release film 100 on the second mold release layer 12 side is preferably 0.01 to 4 μm, more preferably 0.05 to 3 μm, and still more preferably 0.1 to 2 μm.

By setting the surface roughness Ra to be equal to or more than the above-described lower limit value, the mold releasability during molding can be improved. On the other hand, by setting the surface roughness Ra to be equal to or less than the above-described upper limit value, the balance between the mold releasability and favorable appearance of the molded product can be improved.

The same control method of the surface roughness of the surface on the first mold release layer 11 side can be used as a method of controlling the surface roughness of the surface on the second mold release layer 12 side.

In addition, the second mold release layer 12 is a stretched or non-stretched film formed of a second resin composition. Whether the film is stretched or unstretched can be appropriately set, but it is preferable that the film is a stretched film in a case of improving the rigidity of the film, and the film is a non-stretched film in a case of improving the moldability. In addition, the stretching can be obtained by using a known method such as sequential biaxial stretching, simultaneous biaxial stretching, and tubular stretching.

Hereinafter, the second resin composition will be described in detail.

As the second resin composition, the same materials as those exemplified in the first resin composition described above can be exemplified. In addition, the second resin composition may be the same as or different from the first resin composition, but from the viewpoint of effectively suppressing the occurrence of curls at the end part of the mold release film 100, it is preferable that the second resin composition has the same material and composition as the first resin composition.

### [Interlayer 20]

The interlayer 20 is a resin layer located between the first mold release layer 11 and the second mold release layer 12, constituting the mold release surfaces of the mold release film 100. The interlayer 20 in the first embodiment is composed of a resin composition for the interlayer, containing a polyester resin.

A thickness of the interlayer 20 is preferably 20 to 100 μm, more preferably 20 to 70 μm, and still more preferably 25 to 50 μm.

The interlayer 20 is preferably formed into a film using the resin composition for the interlayer. A method of forming the film is not particularly limited, and a known method can be used. For example, a known method such as extrusion, inflation, and calendering can be adopted.

In addition, the interlayer 20 may be a stretched film or a non-stretched film, and the type thereof can be appropriately set, and the stretched film and the non-stretched film may be used in combination. For example, it is preferable that the film is a stretched film in a case of improving the rigidity of the film, and the film is a non-stretched film in a case of improving the moldability. In addition, the stretching can be obtained by using a known method such as sequential biaxial stretching, simultaneous biaxial stretching, and tubular stretching.

In addition, the stretched film and the non-stretched film may be alternately laminated, or the non-stretched film may be laminated between stretched films.

In the first embodiment, the interlayer 20 has a configuration in which two film-like resin compositions for the interlayer are laminated through an adhesive layer.

The adhesive layer is not particularly limited, but is preferably composed of one kind or two or more kinds selected from polyester, polyether, polyisocyanate, and polyurethane. In addition, a thickness of the adhesive layer is not particularly limited, but is, for example, preferably 0.5 to 10 μm and more preferably 1 to 8 μm.

Hereinafter, the resin composition for the interlayer will be described in detail.

### (Polyester Resin)

Examples of the above-described polyester resin include one kind or two or more kinds selected from a polyethylene terephthalate resin (PET), a polyethylene terephthalate glycol resin (PETG), a polybutylene terephthalate resin (PBT), a polytrimethylene terephthalate resin (PTT), a polyhexamethylene terephthalate resin (PHT), and a copolymerized polyethylene terephthalate/isophthalate resin (PET/PEI), Among these, a polyethylene terephthalate resin (PET), a polybutylene terephthalate resin (PBT), or a copolymerized polyethylene terephthalate/isophthalate resin (PET/PEI) is preferable.

The resin composition for the interlayer may contain other components in addition to the polyester resin, as long as the characteristics of the mold release film 100 are not impaired. The other components are not limited, and examples thereof include a thermoplastic resin such as polyolefin and polyamide, particles, a coupling agent, an acid catalyst, a solvent, an antistatic agent, a leveling agent, a dispersing agent, a pigment, a dye, an antioxidant, a flame retardant, and a thermal conductivity improver.

### (Polyolefin Resin)

The above-described polyolefin resin is a resin having a structural unit derived from an α-olefin such as ethylene, propylene, and butene, and a known polyolefin resin can be used. Specific examples of the polyolefin resin include polyethylene (PE) such as low-density polyethylene (LDPE), medium-density polyethylene (MDPE), high-density polyethylene (HDPE), and linear low-density polyethylene (LLDPE); polypropylene (PP); polyvinyl alcohol (PVA); ethylene-vinyl acetate copolymer (EVA); ethylene-methyl acrylate copolymer (EMA); ethylene-acrylic acid copolymer (EAA); ethylene-methyl methacrylate copolymer (EMMA); ethylene-ethyl acrylate copolymer (EEA); ethylene-methacrylic acid copolymer (EMAA); ionomer resin; ethylene-vinyl alcohol copolymer (EVOH); and cyclic olefin resin (COP). These may be used alone or in combination of two or more thereof.

### (Polyamide Resin)

Examples of the above-described polyamide resin include an aliphatic polyamide and an aromatic polyamide. Specific examples of the aliphatic polyamide include polyamide 6, polyamide 6,6, a polyamide 6-6,6 copolymer, polyamide 11, and polyamide 12. Specific examples of the aromatic polyamide include polyamide 61, polyamide 66/6T, polyamide 6T/6, and polyamide 12/6T.

### (Particles)

As the particles, the same particles as those described in the first resin composition above can be used. Among these, from the viewpoint of obtaining heat resistance, inorganic particles are preferable. In this case, a content of the particles is preferably 1% to 40% by mass, more preferably 10% to 30% by mass, and still more preferably 15% to 25% by mass with respect to the total amount of the resin composition for the interlayer.

In the first embodiment, it is preferable that the two-layer interlayer 20 is formed of the same resin composition for the interlayer. For example, as the resin composition for the interlayer of the two-layer interlayer 20, it is suitable that PET and/or PBT is contained as the polyester resin.

The interlayer of the mold release film according to the embodiment of the present invention is not limited to the two layers, and may be a single layer or three or more layers laminated. In addition, the layers may be formed of resin compositions for the interlayer, which are different from each other, or a layer formed of the resin composition for the interlayer may be interposed between layers formed of the same resin composition for the interlayer.

For example, a case in which the interlayer is a three-layer structure will be described.

FIG. 2 is a cross-sectional view showing the case in which the interlayer has a three-layer structure. As shown in FIG. 2, an interlayer 20 of a mold release film 101 has a configuration in which a first interlayer 20a, a second interlayer 20b, and a first interlayer 20a are laminated in this order.

In this case, in a case where the resin composition for the interlayer of the first interlayer 20a contains PBT as the polyester resin, it is suitable that the resin composition for the interlayer of the second interlayer 20b contains PET as the polyester resin. In addition, for example, in a case where the resin composition for the interlayer of the first interlayer 20a contains PET as the polyester resin, it is suitable that the resin composition for the interlayer of the second interlayer 20b contains PBT as the polyester resin.

In addition, in a case where the interlayer 20 has a multilayer structure, the layers may be formed of the same resin composition or may be formed of different resin compositions, but in a case where the layers are formed of different resin compositions, it is preferable that the layer structure of the interlayer is a symmetric structure or symmetric composition. In addition, it is sufficient that the different resin compositions are at least two or more kinds, and the number of layers formed of the same resin composition in the interlayer may be equal to or more than 2.

In addition, the interlayer 20 may be either a stretched film or a non-stretched film, and the first interlayer 20a may be a stretched film and the second interlayer 20b may be a non-stretched film.

### <Method for Manufacturing Mold Release Film>

Next, a method for manufacturing the mold release film 100 according to the first embodiment will be described.

As the method for manufacturing the mold release film 100, a known method can be used, and for example, the mold release film 100 can be manufactured using a known method such as a co-extrusion method, an extrusion laminating method, a dry laminating method, an inflation method, an inflation extrusion method, and a T-die extrusion method. Alternatively, as described above, each layer is formed into a film, and then the films may be laminated by a known method to form the mold release film 100.

Examples thereof include the following methods (i) and (ii).
(i) film-like interlayers 20 are prepared, and a coating liquid (varnish or paste) of the first resin composition constituting the first mold release layer 11 is applied onto one surface of the interlayer 20, and then cured to form the first mold release layer 11, thereby preparing two laminates; the obtained two laminates are superimposed on each other such that the film-like interlayers 20 face each other, and are bonded to each other through the adhesive layer or the like to obtain the mold release film 100; in this case, one of the first mold release layers 11 is the second mold release layer 12.
(ii) a film-like first mold release layer 11, film-like second mold release layer 12, and film-like interlayer 20 are separately prepared, and the first mold release layer 11, the interlayer 20, and the second mold release layer 12 are laminated in this order, and are bonded to each other through lamination processing, the adhesive layer, or the like, thereby obtaining the mold release film 100.

In a case where the first mold release layer 11, the second mold release layer 12, and the interlayer 20 are formed separately, the film can be obtained by a known method such as an extrusion molding method, a calender molding method, a press molding method, and a coating method. In addition, each obtained film can be subjected to a stretching treatment as necessary.

In addition, in a case where the above-described coating method is used, for example, the first resin composition constituting the first mold release layer 11 is uniformly mixed by any kneading device to prepare the coating liquid (varnish or paste), and the coating liquid is applied onto the interlayer 20 to obtain a laminated structure of the interlayer 20 and the first mold release layer 11.

A temperature during the kneading is appropriately set according to the type of the resin, but for example, as a roll set temperature, it is preferably appropriately 10° C. to 70° C. and more preferably appropriately 25° C. to 30° C. In addition, a kneading time is, for example, preferably approximately 5 minutes to 1 hour and more preferably approximately 10 to 40 minutes. A kneading device is not particularly limited, and for example, a kneader, a two-roll mill, a Banbury mixer (continuous kneader), a pressure kneader, or the like can be used.

Next, the obtained coating liquid is applied onto the surface to be coated to form a coating film.

The coating method is not particularly limited, and is performed by various known units. Examples thereof include a roll coater, a reverse roll coater, a gravure coater, a knife coater, and a bar coater. In a case where the lamination structure is formed by winding any of the first mold release layer 11, the second mold release layer 12, or the interlayer 20 around a roll or feeding the same in a roll-to-roll manner, it is preferable to reduce a tension due to winding or feeding as much as possible. In addition, a coating amount is preferably 0.01 to 10 g/m² and more preferably 0.05 to 5 g/m² in terms of weight after curing.

Each coating film can be a desired film by being cured thereafter. A curing condition is, for example, 90° C. to 170° C. for 30 seconds to 5 minutes.

### <Applications and Use Method of Mold Release Film>

In a case of manufacturing a flexible printed circuit board (hereinafter, also referred to as “FPC”) in which a coverlay film (hereinafter, also referred to as “CL film”) is attached to a flexible film in which a circuit is exposed (hereinafter, also referred to as “circuit-exposed film”) through an adhesive by heating press, the mold release film 100 according to the first embodiment is used for a purpose of being disposed between the cover film and the mold. That is, the mold release film may be a so-called mold release film for FPC manufacturing or may be used for other applications.

In addition, examples of other applications include an application in which a sealing resin is provided between a mold to which the sealing resin is supplied and a semiconductor device to be resin-sealed in a resin sealing step of a semiconductor device.

In addition, for example, the mold release film can also be used as a decorative transfer mold release film for performing printing or the like on a product having a three-dimensional shape, such as a mold release film for demolding in a case of curing a prepreg of a thermosetting resin such as CFRP, and a mold release film for molding of a thermosetting resin,

### <Method for Manufacturing Molded Product and Method for Using Mold Release Film>

Next, a method for manufacturing a molded product of the first embodiment will be described.

The method for manufacturing the molded product of the first embodiment includes a step of disposing the mold release film 100 on an object such that one mold release surface (the first mold release layer 11) of the above-described mold release film 100 is on the object side, and a step of performing a heating press on the object on which the mold release film 100 is disposed, in which, in the step of disposing the mold release film 100, a surface of the object on which the mold release film 100 is formed of a material containing a thermosetting resin.

In addition, after the step of disposing the mold release film 100, a step of disposing a material on a surface of the mold release film 100 on the second mold release layer 12 side may be further included.

Regarding the conditions of the heating press, a known method can be used.

As the method for manufacturing the molded product according to the first embodiment, for example, an example of use in a case of manufacturing a flexible printed circuit board will be described.

In this case, the mold release film 100 is used by being interposed between the coverlay and the press machine in a case where the coverlay film is heated and pressed to be closely attached to the circuit in order to protect the circuit formed on the flexible film.

Specifically, the mold release film 100 is used, for example, in a coverlay press laminate step which is one of manufacturing steps of the flexible printed wiring board. More specifically, the mold release film 100 is disposed to cover the coverlay film in order to bring the coverlay film into close contact with an uneven portion of the circuit pattern in a case of adhesion of the coverlay film to the circuit-exposed film, and is heated and pressed by a press machine together with the circuit-exposed film and the coverlay film.

At this time, in order to improve cushioning property, paper, rubber, a fluororesin sheet, glass paper, or the like, or a material in which these are combined can also be inserted between the mold release film 100 and the prese machine, and then heated and pressed.

In addition, the mold release film 100 according to the first embodiment may be used in the following method for manufacturing the above-described molded product.

First, a surface of an object formed of a material containing a thermosetting resin is disposed facing the surface of the above-described mold release film 100 according to the first embodiment on the first mold release layer 11 side. Next, paper, rubber, a fluororesin sheet, glass paper, or the like, or a material in which these are combined is disposed on the surface of the mold release film 100 on the second mold release layer 12 side. Thereafter, the object on which the mold release film 100 is disposed is subjected to a press treatment in a mold. Here, the above-described thermosetting resin may be in a semi-cured state or in a cured state, but in a case where the thermosetting resin is in a semi-cured state, the effects of the mold release film 100 are more remarkable. In particular, in a case where the thermosetting resin is a resin composition containing an epoxy resin, it is preferable that the epoxy resin is in an intermediate stage of a curing reaction, that is, in a B-stage state.

In addition, the mold release film 100 according to the first embodiment can be adopted to a known method such as a roll-to-roll method, a quick press method, and a multi-stage press method. Among these, in a case where the mold release film 100 according to the first embodiment is adopted to a roll-to-roll method or a quick press method, high peelability and favorable followability are easily obtained with the mold release film 100.

In the roll-to-roll method, the pressing method is automated, and the mold release film 100 or the FPC is automatically transported. The mold release film is heated to a predetermined temperature at all times and then immediately peeled off after thermal pressing. The quick press method is a method of setting one surface of an object such as FPC on a press molding machine in which cushion sheets are attached to upper and lower press plates, and performing a thermal pressing, in which the press molding machine is heated to a predetermined temperature at all times. The multi-stage pressing method is a method of performing a thermal pressing through a process of setting a plurality of FPCs on a press molding machine near room temperature in a stacked manner through cushion sheets, pressurizing and heating, and then cooling.

### 2. Second Embodiment

FIG. 3 is a cross-sectional view schematically showing a cross section of a mold release film according to a second embodiment.

As shown in FIG. 3, a mold release film 200 according to the second embodiment has a configuration in which a first mold release layer 11 constituting one mold release surface, an interlayer 20, and a second mold release layer 12 constituting the other mold release surface are laminated in this order, similarly to the mold release film 100 according to the first embodiment. In the first embodiment, the interlayer 20 has a two-layer structure.

Hereinafter, the mold release film 200 according to the second embodiment will be described in detail, but the description of the configuration, the effects, and the like common to the first embodiment will not be repeated.

### (Surface Free Energy)

Since all of the mold release films 200 according to the second embodiment constitute the mold release surface, a surface free energy of at least one surface of the surface on the first mold release layer 11 side or the surface on the second mold release layer 12 side is 15 to 35 [mJ/m³], and a difference between the surface free energies of the two surfaces is less than 2.0.

As a result, it is possible to suppress the sticking property to the mold while maintaining the mold releasability with respect to the molded product.

In addition, by setting the surface free energy to be equal to or less than the above-described upper limit value, adhesiveness is reduced, and favorable mold releasability with respect to the molded product or favorable anti-sticking property to the mold is easily obtained. On the other hand, by setting the surface free energy to be equal to or more than the above-described lower limit value, film-forming properties of the mold release layer can be improved, and stable mold releasability or anti-sticking property can be obtained.

In the second embodiment, in a case where the surface free energy of the surface on the first mold release layer 11 side is denoted by SC1 and the surface free energy of the surface on the second mold release layer 12 side is denoted by SC2, SC1 and SC2 are preferably 15 to 30 [mJ/m³], more preferably 17 to 28 [mJ/m²], and still more preferably 20 to 25 [mJ/m²].

In the second embodiment, the example in which the mold release layer is disposed on both surfaces of the mold release film has been described, but the mold release layer may be disposed on only one surface of the mold release film. That is, a surface on the molded product side may be the mold release layer. In this case, in a case where the surface free energy of the surface of the mold release film on the mold release layer side is denoted by SC1 and the surface free energy of the surface of the mold release film opposite to the mold release layer is denoted by SC2, SC1 may be 15 to 35 [mJ/m²] and |SC1-SC2| may be less than 2.0.

Examples of a method of adjusting the surface free energy include selection of a material of a resin composition for a mold release layer, constituting the mold release layer, particularly, selection of a type of a resin, whether or not the resin film is subjected to a stretching treatment, and adjustment of the surface roughness,

Various theoretical expressions for analyzing the measurement of the surface free energy from the measurement of a contact angle of a solvent have been known, but in the second embodiment, Owens-Wendt method for measuring the surface free energy with two components of the dispersion component and the polar component is suitable.

### (Thermal Dimensional Change Rate)

In the mold release film 200 according to the second embodiment, a thermal dimensional change rate in the MD direction at 180° C., which is measured from 25° C. to 230° C. by a thermomechanical analysis (TMA) method (tensile load: 500 mN, temperature rising rate: 5° C./min), is preferably equal to or less than 9%, more preferably equal to or less than 7%, and still more preferably equal to or less than 5%.

By setting the dimensional change rate to be equal to or less than the upper limit value, the thermal deformation of the mold release film 200 during the heating press is suppressed, and the sticking property to the mold is easily suppressed. In addition, since the curling of the end part of the mold release film 200 according to the second embodiment can be reduced, the mold release film 200 can be satisfactorily subjected to vacuum suction without the end part being folded during the vacuum suction.

### (Tensile Stress)

In the mold release film 200 according to the second embodiment, a tensile stress of the mold release film in the MD direction, which is obtained in a case where a tensile test is performed according to JIS K 7127 under conditions of 180° C. and a load rate of 500 mm/min, is preferably equal to or more than 40 MPa, more preferably equal to or more than 50 MPa, and still more preferably equal to or more than 60 MPa.

By setting the tensile stress to be equal to or more than the above-described lower limit value, even in a case where a tension is applied to the mold release film 200 during transportation, during unwinding, during roll storage, or the like, an appropriate stiffness of the mold release film 200 is maintained, and the thermal deformation of the mold release film 200 during the heating press is suppressed, so that the sticking property to the mold can be easily suppressed. In addition, the curling of the end part of the mold release film 200 according to the second embodiment can be reduced, and the mold release film 200 can be satisfactorily subjected to vacuum suction without the end part being folded during the vacuum suction.

### (Storage Elastic Modulus)

In addition, in the mold release film 200 according to the second embodiment, in a case where a storage elastic modulus of the mold release film at 180° C., which is measured using a dynamic viscoelasticity measuring device (tensile mode, a frequency of 1 Hz, and a temperature rising rate of 5° C./min), is denoted by E′ (180) [MPa] and a storage elastic modulus of the mold release film at 100° C. is denoted by E′ (100) [MPa], E′ (100) -E′ (180) is preferably equal to or more than 350 [MPa], and more preferably equal to or more than 500 [MPa].

That is, the mold release film is deformed by the heating press, but since the mold release film 200 according to the second embodiment has a high storage elasticity rate, an appropriate storage elasticity rate can be maintained even during the pressing. As a result, it is possible to maintain favorable mold releasability with respect to the molded product while suppressing adhesion to the mold after the heating press.

The above-described dimensional change rate, storage elasticity rate, and tensile stress of the mold release film 200 according to the second embodiment can be realized, for example, by selecting and combining known methods such as the type of raw materials and the film forming method of the first mold release layer 11 and the second mold release layer 12, the type of raw materials and the film forming method of the interlayer 20, the control of the surface roughness of the mold release film 200, and the method for manufacturing the mold release film 200, and by using a method different from the related art.

For example, in a case where the film is formed by a film forming method of stretching the film, a film having a hardness and a stiffness can be formed as compared with a non-stretched film. In addition, as an example of the method for manufacturing the mold release film 200 according to the second embodiment, in a roll-to-roll method, a coating liquid of a resin composition for a mold release layer, which constitutes the first mold release layer 11 or the second mold release layer 12, may be applied onto one surface of the interlayer 20. In this case, in a case where a transport tension of the film is too high, excessive stress is applied to the first mold release layer 11 or the second mold release layer 12. Therefore, by setting the transport tension of the roll in the roll-to-roll method to be equal to or less than 100 N, the stress applied to the first mold release layer 11 or the second mold release layer 12 can be reduced, and the desired mold release film 200 can be obtained.

### (Symmetry)

It is preferable that the mold release film 200 has a symmetrical structure and/or a symmetrical composition with respect to a center plane in a direction perpendicular to a thickness direction of the mold release film, similarly to the above-described mold release film 100. The details of the symmetry of the mold release film 200 are the same as those described in the mold release film 100 above.

### (Thickness)

A thickness of the mold release film 200 is the same as the thickness described in the mold release film 100 above.

In addition, the details of each layer provided in the mold release film 200 according to the second embodiment are the same as the details of each layer described in the mold release film 100 above.

In addition, a method for manufacturing the mold release film 200 of the second embodiment is the same as the method for manufacturing the mold release film 100 described above.

In addition, the applications and the use method of the mold release film 200 according to the second embodiment, the method for manufacturing a molded product, and the use method of the mold release film 200 are the same as the applications and the use method of the mold release film 200, the method for manufacturing the molded product, and the use method of the mold release film 200, which are described in the mold release film 100 above.

### 3. Third Embodiment

FIG. 3 is a cross-sectional view schematically showing a cross section of a mold release film according to a third embodiment.

As shown in FIG. 3, a mold release film 200 according to the third embodiment has a configuration in which a first mold release layer 11 (first resin layer) constituting one mold release surface, an interlayer 20 (second resin layer) formed of a resin composition different from the first mold release layer 11, and a second mold release layer 12 (third resin layer) constituting the other mold release surface are laminated in this order, similarly to the mold release film 100 according to the first embodiment. In the third embodiment, the interlayer 20 has a two-layer structure in which a first interlayer 20a, a second interlayer 20b, and a first interlayer 20a are laminated in this order.

Hereinafter, the mold release film 300 according to the third embodiment will be described in detail, but the description of the configuration, the effects, and the like common to the first embodiment will not be repeated.

### (Thermal Dimensional Change Rate)

In the mold release film 300 according to the third embodiment, in a case where a thermal dimensional change rate is measured according to the following procedure a, a thermal dimensional change rate At of the mold release film at 180° C. in a width direction (TD) is equal to or less than 2.58, and a difference between a thermal dimensional change rate Am of the mold release film at 180° C. in a length direction (MD) and the thermal dimensional change rate At of the mold release film at 180° C. in the width direction (TD) is equal to or less than 5.0%.

Procedure a: using a thermo-mechanical analyzer, a thermal dimensional change rate of the mold release film is measured by heating the mold release film from 20° C. to 210° C. at a temperature rising rate of 5° C./min in a state in which a load of 10 mN is applied to the mold release film.

The thermal dimensional change rate of the mold release film 300 according to the third embodiment at 180° C. is intended to represent a behavior of the mold release film 300 being heated and pressed in a mold during use to be thermally shrunk.

Here, since the mold release film 300 is fed in one direction during film formation, the mold release film 300 tends to shrink in the MD direction. Therefore, from the viewpoint of suppressing wrinkles and curls, it is effective to make a thermal shrinkage in the ID direction of the mold release film 300 close to a thermal shrinkage in the MD direction.

In addition, in the procedure a, it is considered that the use conditions of the mold release film 300 in the mold can be closer by setting the load to a low tension of 10 mN, and thermal shrinkage behavior of the mold release film 300 can be more accurately controlled.

Therefore, in the third embodiment, the mold release film 300 is configured such that, with regard to the thermal dimension change rate at 180° C., the thermal dimension change rate At in the width direction (TD) is equal to or less than 2.5% and the difference between the thermal dimension change rate Am in the length direction (MD) and the thermal dimension change rate At in the width direction (TD) is equal to or less than 5.08. As a result, it is considered that, in a case where the mold release film 300 is thermally shrinked, the mold release film 300 can be shrinked in a balanced manner in the length direction (MD) and the width direction (TD), and the occurrence of wrinkles and curls can be effectively suppressed.

The thermal dimensional change rate At of the mold release film in the width direction (TD) at 180° C. is equal to or less than 2.5%, preferably equal to or less than 2.0%, more preferably equal to or less than 1,5%, and still more preferably equal to or less than 1.0%.

By setting the thermal dimensional change rate At to be equal to or less than the above-described upper limit value, it is possible to suppress the occurrence of wrinkles in the mold release film 300 in use along the MD direction.

In addition, the difference (absolute value) between the thermal dimensional change rate Am in the length direction (MD) of the mold release film at 180° C. and the thermal dimensional change rate At in the width direction (TD) of the mold release film at 180° C. is equal to or less than 5.0%, preferably equal to or less than 4.8%, more preferably equal to or less than 4.6%, and still more preferably equal to or less than 4.5%.

By setting the difference (absolute value) between the thermal dimension change rate Am and the thermal dimension change rate At to be equal to or less than the above-described upper limit value, it is possible to reduce anisotropy during the thermal shrinkage of the mold release film 300, and to suppress the occurrence of wrinkles and curls.

In addition, the thermal dimensional change rate Am of the mold release film in the length direction (MD) at 180° C. is preferably equal to or less than 0%, preferably equal to or less than-1.0%, and still more preferably equal to or less than-1.5%.

By setting the thermal dimensional change rate Am to be equal to or less than the above-described upper limit value, in a case of using the mold release film 300, the occurrence of the surplus of the mold release film 300 with respect to the mold is suppressed, and the occurrence of wrinkles and curls can be reduced.

1.0 In the mold release film 300 according to the third embodiment, in a case where a thermal dimensional change rate is measured according to the following procedure b, a thermal dimensional change rate Bm of the mold release film in the length direction (MD) at 180° C. is preferably equal to or more than 0.1%, and more preferably equal to or more than 0.2%. By setting the thermal dimensional change rate Bm to be equal to or less than the above-described upper limit value, the mold release film 300 can be used while maintaining favorable moldability with respect to the mold without curling.

Procedure b: using a thermo-mechanical analyzer, a thermal dimensional change rate of the mold release film is measured by heating the mold release film from 20° C. to 210° C. at a temperature rising rate of 5° C./min in a state in which a load of 500 mN is applied to the mold release film.

In addition, in a case where the heat dimension change rate is measured according to the procedure b, a heat dimension change rate Bt of the mold release film in the length direction (TD) at 180° C. is preferably equal to or more than 3.08, and more preferably equal to or more than 3,2%. By setting the thermal dimensional change rate Bm to be equal to or more than the above-described lower limit value, the mold release film 300 can be used while maintaining favorable moldability with respect to the mold without curling.

In the procedure b, it is assumed that a high tension with a load of 500 mN is applied such that the mold release film 300 is closely attached along the inner surface shape of the cavity concave portion of the lower mold by suction or the like. By controlling the thermal shrinkage behavior of the mold release film 300 in a case of the high tension, more favorable mold followability can be exhibited.

The above-described thermal dimensional change rate of the mold release film 300 according to the third embodiment can be realized by appropriately combining the type of the raw material of the interlayer 20, the layer configuration, the film forming method, and the like.

For example, in a case where a stretched film is used as the interlayer 20 in a film forming method, a film having a hardness and a stiffness can be formed as compared with a non-stretched film. In addition, examples thereof include controlling a shrinkage direction of the film by performing post-treatment such as offline embossing. In addition, the interlayer 20 may have a multilayer structure in which layers are formed of different resin materials.

### (Layer Configuration)

The mold release film 300 according to the third embodiment has a symmetrical structure and a symmetrical composition with respect to a center plane in a direction perpendicular to a thickness direction. In a case where the mold release film 300 is divided into two in the thickness direction, the upper layer and the lower layer are symmetrical to each other. As a result, the mold release film 300 can be used without regard to the front and back in a case of using the mold release film 300.

The symmetric structure means that, in a case where the mold release film 300 is divided into two in upper and lower directions with the center plane in the direction perpendicular to the thickness direction as a reference, the structures such as the thicknesses of the upper layer and the lower layer, the surface roughness of the mold release surface, and the layer configuration are the same. In the third embodiment, the center plane in the direction perpendicular to the thickness direction of the mold release film 300 is a ½ surface of the interlayer 20b in the thickness direction. Since the thicknesses of the first mold release layer 11 and the second mold release layer 12, the surface roughness of each mold release surface, the layer configuration of the mold release film 300, and the like are the same, the mold release film 300 has a symmetrical structure.

Examples of the surface roughness include a maximum height Rz and an arithmetic mean roughness Ra, measured according to JIS B 0601:2013. In addition, in the third embodiment, the “structures are the same” is not limited to a case where measured values are completely matched, and includes a measurement error and a minute difference generated in manufacturing.

The symmetrical composition means that, in a case where the mold release film 300 is divided into two in upper and lower directions with the center plane in the direction perpendicular to the thickness direction as a reference, the layer configurations constituting the upper layer and the lower layer are the same, and each layer is composed of the same material.

In the third embodiment, in a case where the mold release film 300 is divided into two in upper and lower directions with the center plane in the direction perpendicular to the thickness direction as a reference, the upper layer includes the first mold release layer 11 and the interlayer 20 (the interlayer 20a and half of the interlayer 20b), and the lower layer includes the second mold release layer 12 and the interlayer 20 (the interlayer 20a and half of the interlayer 20b). In the third embodiment, it is preferable that the first mold release layer 11 and the second mold release layer 12 are composed of the same material.

### (Thickness)

A thickness of the mold release film 300 is the same as the thickness described in the mold release film 300 above.

Hereinafter, each layer included in the mold release film 300 according to the third embodiment will be described in detail.

### [First Mold Release Layer (First Resin Layer)]

The first mold release layer 11 in the third embodiment constitutes one mold release surface of the mold release film 300, and in a case where the mold release film 300 is disposed on the mold, the first mold release layer 11 is a resin layer constituting a surface on a side in contact with a molded product later.

A thickness of the first mold release layer 11 is preferably 0.01 to 50 μm, more preferably 0.05 to 30 μm, still more preferably 0.08 to 25 μm, and particularly preferably 0.1 to 15 μm.

By setting the thickness of the first mold release layer 11 to be equal to or more than the above-described lower limit value, it is possible to impart mold releasability required for the mold release film 300. On the other hand, by setting the thickness of the first mold release layer 11 to be equal to or less than the above-described upper limit value, the rigidity of the mold release film 300 can be controlled, and the balance between the followability and the mold releasability can be improved.

In addition, from the viewpoint of mold releasability and appearance of the molded product, a surface roughness Ra of the surface of the mold release film 300 on the first mold release layer 11 side is preferably 0.01 to 4 μm, more preferably 0.05 to 3 μm, and still more preferably 0.1 to 2 μm.

By setting the surface roughness Ra to be equal to or more than the above-described lower limit value, the mold releasability during molding can be improved. On the other hand, by setting the surface roughness Ra to be equal to or less than the above-described upper limit value, the balance between the mold releasability and favorable appearance of the molded product can be improved.

As a control method of the surface roughness of the surface on the first mold release layer 11 side, the surface roughness can be adjusted by a known method such as transferring the film with an embossed pattern using a roll subjected to an embossing process in the manufacturing step of the mold release film, or blending particles into the material constituting the first mold release layer 11.

The surface roughness Ra of the first mold release layer 11 is measured according to JIS B 0601:2013.

In the third embodiment, the first mold release layer 11 is formed of a first resin composition.

In addition, the first mold release layer 11 may be a stretched or non-stretched film formed of the first resin composition. Whether the film is stretched or unstretched can be appropriately set, but it is preferable that the film is a stretched film in a case of improving the rigidity of the film, and the film is a non-stretched film in a case of improving the moldability. In addition, the stretching can be obtained by using a known method such as sequential biaxial stretching, simultaneous biaxial stretching, and tubular stretching.

In the third embodiment, the details of the first resin composition are the same as the details of the first resin composition described in the first embodiment above.

### [Second Mold Release Layer (Third Resin Layer)]

In the third embodiment, the second mold release layer 12 is a surface opposite to the first mold release layer 11, and is the other mold release surface of the mold release film 300. In addition, in a case where the mold release film 300 is disposed on the mold, the second mold release layer 12 is a resin layer constituting a surface on a side in contact with the mold.

A thickness of the second mold release layer 12 is preferably 0.01 to 50 μm, more preferably 0.05 to 30 μm, still more preferably 0.08 to 25 μm, and still more preferably 0.1 to 15 μm.

By setting the thickness of the second mold release layer 12 to be equal to or more than the above-described lower limit value, the wrinkles can be suppressed, the rigidity can be increased, and the sticking property can be improved. On the other hand, by setting the thickness of the second mold release layer 12 to be equal to or less than the above-described upper limit value, the flexibility of the mold release film 300 is improved, and favorable mold followability is easily obtained.

The thickness of the second mold release layer 12 may be the same as or different from that of the first mold release layer 11, but from the viewpoint of constituting the symmetrical structure or the symmetrical composition, it is preferable to be the same.

In addition, from the viewpoint of mold releasability and appearance of the molded product, a surface roughness Ra of the surface of the mold release film 300 on the second mold release layer 12 side is preferably 0.01 to 4 μm, more preferably 0.05 to 3 μm, and still more preferably 0.1 to 2 μm.

By setting the surface roughness Ra to be equal to or more than the above-described lower limit value, the mold releasability during molding can be improved. On the other hand, by setting the surface roughness Ra to be equal to or less than the above-described upper limit value, the balance between the mold releasability and favorable appearance of the molded product can be improved.

The same control method of the surface roughness of the surface on the first mold release layer 11 side can be used as a method of controlling the surface roughness of the surface on the second mold release layer 12 side.

In addition, the second mold release layer 12 may be a stretched or non-stretched film formed of a second resin composition. Whether the film is stretched or unstretched can be appropriately set, but it is preferable that the film is a stretched film in a case of improving the rigidity of the film, and the film is a non-stretched film in a case of improving the moldability. In addition, the stretching can be obtained by using a known method such as sequential biaxial stretching, simultaneous biaxial stretching, and tubular stretching.

In the third embodiment, the details of the second resin composition are the same as the details of the first resin composition described in the first embodiment above.

### [Interlayer (Second Resin Layer)]

The interlayer 20 is formed of a resin composition different from the first mold release layer 11.

In the third embodiment, the interlayer 20 is a resin layer located between the first mold release layer 11 and the second mold release layer 12, constituting the mold release surfaces of the mold release film 300.

In addition, as shown in FIG. 1, the interlayer 20 has a configuration in which a first interlayer 20a, a second interlayer 20b, and a first interlayer 20a are laminated in this order.

A thickness of the interlayer 20 is preferably 20 to 100 μm, more preferably 20 to 70 μm, and still more preferably 25 to 50 μm.

In addition, thicknesses of the first interlayer 20a and the second interlayer 20b are each preferably 5 to 50 μm, more preferably 7 to 40 μm, and still more preferably 10 to 30 μm.

The interlayer 20 in the third embodiment is composed of a resin composition for the interlayer, containing a polyester resin.

In the third embodiment, the details of the resin composition for the interlayer are the same as the details of the first resin composition described in the first embodiment above.

The interlayer 20 is preferably formed into a film using the resin composition for the interlayer. A method of forming the film is not particularly limited, and a known method can be used. For example, a known method such as extrusion, inflation, and calendering can be adopted.

In addition, the interlayer 20 may be a stretched film or a non-stretched film, and the type thereof can be appropriately set. For example, it is preferable that the film is a stretched film in a case of improving the rigidity of the film, and the film is a non-stretched film in a case of improving the moldability. In addition, the stretching can be obtained by using a known method such as sequential biaxial stretching, simultaneous biaxial stretching, and tubular stretching.

In the third embodiment, films formed of the above-described resin composition for the interlayer are laminated through an adhesive layer to form the interlayer 20.

The adhesive layer is not particularly limited, but is preferably composed of one kind or two or more kinds selected from polyester, polyether, polyisocyanate, and polyurethane. In addition, a thickness of the adhesive layer is not particularly limited, but is, for example, preferably 0.5 to 10 μm and more preferably 1 to 8 μm.

It is preferable that the first interlayer 20a and the second interlayer 20b are composed of different resin compositions for the interlayer. As a result, the thermal dimension change rate At and the thermal dimension change rate Am of the mold release film 300 can be easily controlled at a high degree.

For example, in a case where the resin composition for the interlayer of the first interlayer 20a contains PBT as the polyester resin, it is suitable that the resin composition for the interlayer of the second interlayer 20b contains PET as the polyester resin. In addition, for example, in a case where the resin composition for the interlayer of the first interlayer 20a contains PET as the polyester resin, it is suitable that the resin composition for the interlayer of the second interlayer 20b contains PBT as the polyester resin. In addition, as the resin composition for the interlayer of the first interlayer 20a or the first interlayer 20b, a resin including PET and a polyester copolymer other than PET may be used.

The mold release film 300 has been described above, but the mold release film according to the embodiment of the present invention is not limited thereto, and various configurations can be adopted.

For example, the case in which the mold release film 300 includes the mold release layer on both surfaces has been described, but the mold release layer may be disposed only on one surface of the mold release film.

In addition, the case in which the interlayer 20 in the mold release film 300 has a three-layer structure has been described, but the interlayer may be a single layer or a multilayer structure of equal to or more than four layers. In addition, in a case where the interlayer 20 has a multilayer structure, the layers may be formed of the same resin composition or may be formed of different resin compositions, but in a case where the layers are formed of different resin compositions, it is preferable that the layer structure of the interlayer is a symmetric structure or symmetric composition. In addition, it is sufficient that the different resin compositions are at least two or more kinds, and the number of layers formed of the same resin composition in the interlayer may be equal to or more than 2.

### <Applications and Use Method of Mold Release Film>

The mold release film 300 according to the third embodiment is used for an application in which a sealing resin is provided between a mold to which the sealing resin is supplied and a semiconductor device to be resin-sealed in a resin sealing step of a semiconductor device. That is, the mold release film may be a so-called mold release film for molding or may be used for other applications. As other applications, for example, in a case of manufacturing a flexible printed circuit board (hereinafter, also referred to as “FPC”) in which a coverlay film (hereinafter, also referred to as “CL film”) is attached to a flexible film in which a circuit is exposed (hereinafter, also referred to as “circuit-exposed film”) through an adhesive by heating press, the mold release film 300 according to the third embodiment can be used for a purpose of being disposed between the cover film and the mold. In addition, for example, the mold release film 300 according to the third embodiment can also be used as a decorative transfer mold release film for performing printing or the like on a product having a three-dimensional shape, such as a mold release film for demolding in a case of curing a prepreg of a thermosetting resin such as CFRP, and a mold release film for molding of a thermosetting resin.

Hereinafter, an example of a method for manufacturing a resin-sealed semiconductor device using the mold release film 300 will be described.

The method for manufacturing a resin-sealed semiconductor device includes the following steps,
(Step 1) Preparation step of semiconductor device
(Step 2) Installation step of mold release film
(Step 3) Supplying step of sealing resin
(Step 4) Curing step
(Step 5) Demolding step of molded product
Details of each step will be described.

### (Step 1) Preparation Step of Semiconductor Device

A semiconductor device is obtained by electrically connecting an electrode pad on a circuit wiring provided on a support with an electrode provided in a semiconductor element.

Examples of the semiconductor element include an optical element such as a light emitting element and a light receiving element. Examples of the light emitting element include a light emitting diode (LED) chip, and examples of the light receiving element include an image sensor.

In addition, the support is a substrate formed in any shape such as a circular shape or a polygonal shape. Examples of the support include a ceramic substrate, a silicone substrate, a metal substrate, a rigid substrate such as an epoxy resin and a BT resin, and a flexible substrate such as a polyimide resin and a polyethylene substrate.

### (Step 2) Installation Step of Mold Release Film

The mold release film 300 is disposed in a lower mold having a cavity concave portion for supplying the sealing resin. At this time, the mold release surface of the first mold release layer 11 of the mold release film 300 is disposed on the front side, that is, is in contact with the sealing resin to be supplied later.

In addition, the mold release film 300 is disposed along the surface of the cavity concave portion in the lower mold and a plane portion surrounding the cavity concave portion. At this time, a suction port for causing the mold release film 300 to follow the shape of the cavity concave portion of the lower mold is provided in the plane portion surrounding the cavity concave portion. The suction port is used to suction and discharge air, water, gas, and the like in a space between the mold release film 300 and the mold using a suction device or the like, and the air suction is performed. Furthermore, in order to firmly fix the mold release film 300 to the mold, the mold release film 300 may be sandwiched by a chuck mechanism disposed at a position corresponding to an outer peripheral portion of a sealing resin injection region, the entire outer peripheral portion of the mold release film 300, or the entire outer peripheral portion of the mold.

Examples of the mold include a known mold and a resin mold.

### (Step 3) Supplying Step of Sealing Resin

Next, a sealing resin is supplied to a region of the mold, which is a concave portion where the mold release film 300 is disposed. A known method can be used as the supplying method. In addition, as the sealing resin, a known resin can be used, and examples thereof include one kind of a silicone-based resin, an epoxy-based resin, an acrylic resin, a fluorine-based resin, a polyimide-based resin, a silicone-modified epoxy-based resin, and the like, mixtures of these resins, and precursors of these resins.

In the third embodiment, in a case where the mold release film 300 is adopted to a compression molding method (compression molding method), it is preferable that the sealing resin is processed into a tablet-like, granule-like, sealed-granule-like, or sheet-like shape.

In the mold, the sealing resin is heated to a predetermined temperature and is in a flow state.

### (Step 4) Curing Step

Next, in order to prevent the molding target from falling, the semiconductor device serving as a molded object is attached to the upper mold provided with the fixture of the protrusion for holding the outer edge of the molded object such that the surface of the semiconductor element of the semiconductor device is facing the lower mold, and the semiconductor device is brought into contact with the mold in which the sealing resin is supplied to the concave portion. At this time, the fixing piece of the upper mold is fitted into the groove portion of the lower mold, and the semiconductor element is covered with the sealing resin. The sealing resin is heated and pressurized to be cured, thereby obtaining a molded product.

In a case where the sealing resin is a precursor of the curable resin, the sealing resin may be cured by heating and irradiation with active energy ray. Examples of the above-described active energy ray include radiation, ultraviolet rays, visible light, and electron beams.

### (Step 5) Demolding Step of Molded Product

Thereafter, the molded product is removed from the mold. In the demolding step of the molded product, the mold release film 300 is released from the mold and the molded product is demolded by supplying air, water, gas, or the like between the mold release film 300 and the mold, At the same time as or after this, the mold release film 300 is released from the molded product.

In a case where one semiconductor element is provided on the support, the molded product is the resin-sealed semiconductor device.

As a result, a semiconductor device having favorable appearance is obtained.

### <Molding Material Set for Manufacturing Mold Release Film>

A molding material set for the interlayer 20, which is used in a case of manufacturing the mold release film 300 according to the third embodiment, including the first mold release layer 11 (first resin layer) constituting one mold release surface and the interlayer 20 (second resin layer) formed of a resin composition different from the first mold release layer 11, in which the first mold release layer 11 and the interlayer 20 are laminated,
in which the interlayer 20 is a film, and
in a case where a thermal dimensional change rate is measured according to the following procedure c, a thermal dimensional change rate Ct of the mold release film at 180° C. in a width direction (TD) is equal to or less than 2.5%, and a difference between a thermal dimensional change rate Cm of the mold release film at 180° C. in a length direction (MD) and the thermal dimensional change rate Ct of the mold release film at 180° C. in the width direction (TD) is equal to or less than 5.0%.

Procedure c: using a thermo-mechanical analyzer, a thermal dimensional change rate of the film is measured by heating the film from 20° C. to 210° C. at a temperature rising rate of 5° C./min in a state in which a load of 10 mN is applied to the film.

By manufacturing the mold release film 300 using the molding material set according to the third embodiment, it is possible to suppress the occurrence of wrinkles in the mold release film 300.

The interlayer 20 can have the same configuration, material, manufacturing method, and the like as those described in the mold release film 300 above.

The molding material set according to the third embodiment contains at least a material for forming the interlayer 20 of the mold release film 300, and may further contain a material for forming the first mold release layer 11.

A method for manufacturing the mold release film 300 can be the same as the above-described method.

The embodiments of the present invention have been described above, but these are examples of the present invention and various configurations other than the above can be adopted. In addition, the present invention is not limited to the above-described embodiments, and modifications, improvements, and the like within the range in which the object of the present invention can be achieved are included in the present invention.

An example of a reference aspect of the present invention is shown below.

1. A mold release film including:
a first mold release layer constituting one mold release surface;
an interlayer; and
a second mold release layer constituting the other mold release surface,
in which the first mold release layer, the interlayer, and the second mold release layer are laminated in this order, and
in which the interlayer is composed of a resin composition for the interlayer, containing a polyester resin.

2. The mold release film according to 1.,
in which the mold release film has a symmetrical structure and/or a symmetrical composition with respect to a center plane in a direction perpendicular to a thickness direction of the mold release film.

3. The mold release film according to 1, or 2.,
in which the first mold release layer and the second mold release layer are each composed of a resin composition for a mold release layer, containing one kind or two or more kinds selected from a silicone resin, a fluororesin, a melamine resin, an epoxy resin, a phenol resin, and an acrylic resin.

4. The mold release film according to any one of 1. to 3.,
in which the polyester resin includes one kind or two or more kinds selected from a polyethylene terephthalate resin (PET), a polyethylene terephthalate glycol resin (PETG), a polybutylene terephthalate resin (PBT), a polytrimethylene terephthalate resin (PTT), a polyhexamethylene terephthalate resin (PHT), and a copolymerized polyethylene terephthalate/isophthalate resin (PET/PEI).

5. The mold release film according to any one of 1. to 4.,
in which a thickness of the interlayer is 20 to 100 μm.

6. The mold release film according to any one of 1. to 5.
in which a tensile stress of the mold release film in an MD direction, which is obtained in a case where a tensile test is performed according to JIS K 7127 under conditions of 180° C. and a load rate of 500 mm/min, is equal to or more than 40 MPa.

7. The mold release film according to any one of 1. to 6.,
in which the interlayer is obtained by laminating a plurality of films formed of the resin composition for the interlayer.

8. The mold release film according to 7.,
in which the interlayer is obtained by laminating the plurality of films through an adhesive layer.

9. The mold release film according to 8.,
in which the adhesive layer is composed of one kind or two or more kinds selected from polyester, polyether, polyisocyanate, and polyurethane.

10. The mold release film according to 8, or 9.,
in which a thickness of the adhesive layer is 0.5 to 10 μm.

11. The mold release film according to any one of 1. to 10.,
in which the interlayer includes a stretched film formed of the resin composition for the interlayer.

12. A mold release film including:
a first mold release layer over at least one surface,
in which, in a case where a surface free energy of the one surface of the mold release film is denoted by SC1 and a surface free energy of the other surface of the mold release film is denoted by SC2, SC1 is 15 to 35 [mJ/m³] and |SC1-SC2| is less than 2.0.

13. The mold release film according to 12.,
in which a thermal dimensional change rate at 180° C. in an MD direction, which is measured by a thermomechanical analysis (TMA) method, is equal to or less than 9%.

14. The mold release film according to 12, or 13.,
in which, in a case where a storage elastic modulus of the mold release film at 180° C., which is measured using a dynamic viscoelasticity measuring device (tensile mode, a frequency of 1 Hz, and a temperature rising rate of 5° C./min), is denoted by E′ (180) [MPa] and a storage elastic modulus of the mold release film at 100° C. is denoted by E′ (100) [MPa], E′ (100)-E′ (180) is equal to or more than 350 [MPa].

15. The mold release film according to any one of 12. to 14.,
in which a tensile stress of the mold release film in an MD direction, which is obtained in a case where a tensile test is performed according to JIS K 7127 under conditions of 180° C. and a load rate of 500 mm/min, is equal to or more than 40 MPa.

16. The mold release film according to any one of 12. to 15., further including:
an interlayer over a surface of the first mold release layer opposite to a mold release surface side,
in which the interlayer is composed of a resin composition for the interlayer, containing a polyester resin.

17. The mold release film according to any one of 12. to 16., further including:
a second mold release layer over the other surface.

18. The mold release film according to 17.,
in which the mold release film has a symmetrical structure and/or a symmetrical composition with respect to a center plane in a direction perpendicular to a thickness direction of the mold release film.

19. The mold release film according to 17, or 18.,
in which the first mold release layer and the second mold release layer are each composed of a resin composition for a mold release layer, containing one kind or two or more kinds selected from a silicone resin, a fluororesin, a melamine resin, an epoxy resin, a phenol resin, and an acrylic resin.

20. The mold release film according to 16.,
in which the polyester resin includes one kind or two or more kinds selected from a polyethylene terephthalate resin (PET), a polyethylene terephthalate glycol resin (PETG), a polybutylene terephthalate resin (PBT), a polytrimethylene terephthalate resin (PTT), a polyhexamethylene terephthalate resin (PHT), and a copolymerized polyethylene terephthalate/isophthalate resin (PET/PEI).

21. The mold release film according to 16, or 20.,
in which a thickness of the interlayer is 20 to 100 μm.

22. The mold release film according to 16., 20. or 21.,
in which the interlayer is obtained by laminating a plurality of films formed of the resin composition for the interlayer.

23. The mold release film according to 22.,
in which the interlayer is obtained by laminating the plurality of films through an adhesive layer.

24. The mold release film according to 23.,
in which the adhesive layer is composed of one kind or two or more kinds selected from polyester, polyether, polyisocyanate, and polyurethane.

25. The mold release film according to 23, or 24., in which a thickness of the adhesive layer is 0.5 to 10 μm.

26. The mold release film according to any one of 16. to 25.,
in which the interlayer includes a stretched film formed of the resin composition for the interlayer.

27. A mold release film including:
a first resin layer as a mold release surface, and
a second resin layer formed of a resin composition different from the first resin layer,
in which the first resin layer and the second resin layer are laminated, and
in which, in a case where a thermal dimensional change rate is measured according to the following procedure a, a thermal dimensional change rate At of the mold release film at 180° C. in a width direction (TD) is equal to or less than 2.5%, and a difference between a thermal dimensional change rate Am of the mold release film at 180° C. in a length direction (MD) and the thermal dimensional change rate At of the mold release film at 180° C. in the width direction (TD) is equal to or less than 5.0%,
procedure a: using a thermo-mechanical analyzer, a thermal dimensional change rate of the mold release film is measured by heating the mold release film from 20° C. to 210° C. at a temperature rising rate of 5° C./min in a state in which a load of 10 mN is applied to the mold release film.

28. The mold release film according to 27.,
in which the thermal dimensional change rate Am of the mold release film at 180° C. in the length direction (MD) is equal to or less than 0%.

29. The mold release film according to 27, or 28.,
in which, in a case where a thermal dimensional change rate is measured according to the following procedure b, a thermal dimensional change rate Bm of the mold release film at 180° C. in the length direction (MD) is equal to or more than 0.1%,
procedure b: using a thermo-mechanical analyzer, a thermal dimensional change rate of the mold release film is measured by heating the mold release film from 20° C. to 210° C. at a temperature rising rate of 5° C./min in a state in which a load of 500 mN is applied to the mold release film.

30. The mold release film according to any one of 27. to 29.,
in which, in a case where a thermal dimensional change rate is measured according to the following procedure b, a thermal dimensional change rate Bt of the mold release film at 180° C. in the length direction (MD) is equal to or more than 3.0%,
procedure b: using a thermo-mechanical analyzer, a thermal dimensional change rate of the mold release film is measured by heating the mold release film from 20° C. to 210° C. at a temperature rising rate of 5° C./min in a state in which a load of 500 mN is applied to the mold release film.

31. The mold release film according to any one of 27, to 30.,
in which the first resin layer is composed of a resin composition for a surface layer, containing one kind or two or more kinds selected from a silicone resin, a fluororesin, a melamine resin, an epoxy resin, a phenol resin, and an acrylic resin.

32. The mold release film according to any one of 27. to 31.;
in which the mold release film has a symmetrical structure and/or a symmetrical composition with respect to a center plane in a direction perpendicular to a thickness direction of the mold release film.

33. The mold release film according to any one of 27. to 32., further including:
a third resin layer as a mold release surface, which is provided over a surface of the mold release film opposite to the first resin layer.

34. The mold release film according to any one of 27. to 33.
in which the second resin layer is composed of a resin composition for the second resin layer, containing a polyester resin.

35. The mold release film according to 34.,
in which the polyester resin includes one kind or two or more kinds selected from a polyethylene terephthalate resin (PET), a polyethylene terephthalate glycol resin (PETG), a polybutylene terephthalate resin (PBT), a polytrimethylene terephthalate resin (PTT), a polyhexamethylene terephthalate resin (PHT), and a copolymerized polyethylene terephthalate/isophthalate resin (PET/PEI).

36. The mold release film according to 34, or 35.,
in which the second resin layer is obtained by laminating a plurality of films formed of the resin composition for the Second resin layer.

37. The mold release film according to any one of 34. to 36.,
in which the second resin layer includes a stretched film.

38. The mold release film according to 37.,
in which the film is laminated through an adhesive layer.

39. The mold release film according to 38.,
in which the adhesive layer is composed of one kind or two or more kinds selected from polyester, polyether, polyisocyanate, and polyurethane.

40. The mold release film according to 38, or 39.,
in which a thickness of the adhesive layer is 0.5 to 10 μm.

41. A molding material set for a second resin layer, which is used in a case of manufacturing a mold release film including a first resin layer as a mold release surface and the second resin layer formed of a resin composition different from the first resin layer, in which the first resin layer and the second resin layer are laminated,
in which the second resin layer is a film, and
in which, in a case where a thermal dimensional change rate is measured according to the following procedure c, a thermal dimensional change rate Ct of the mold release film at 180° C. in a width direction (TD) is equal to or less than 2.5%, and a difference between a thermal dimensional change rate Cm of the mold release film at 180° C. in a length direction (MD) and the thermal dimensional change rate Ct of the mold release film at 180° C. in the width direction (TD) is equal to or less than 5.0%,
procedure c: using a thermo-mechanical analyzer, a thermal dimensional change rate of the film is measured by heating the film from 20° C. to 210° C. at a temperature rising rate of 5° C./min in a state in which a load of 10 mN is applied to the film.

### EXAMPLES

Hereinafter, the present invention will be described in detail with reference to Examples, but the present invention is not limited to the description of Examples.

### 1. First Experiment

### (1) Raw Materials of Mold Release Layer

Melamine-based mold release agent (melamine; manufactured by Arakawa Chemical Industries, Ltd., ARACOAT, RL3021 (main agent)/RA2000 (curing agent)) (solid content: 10% by mass, solvent: IPA)
Acrylic mold release agent (acrylic; manufactured by TOKUSHIKI CO., Ltd., SQ100 (main agent)/UAX-615 (curing agent)) (solid content: 10% by mass, solvent: ethyl acetate)
Silicone-based mold release agent (silicone; self-formulated) (solid content amount: 20% by mass, solvent: toluene)

### (2) Raw Materials of Interlayer

OPBT: biaxially stretched polybutylene terephthalate film (BOBLET (registered trademark) ST, manufactured by KOHJIN Film & Chemicals Co., Ltd.)
OPET: biaxially stretched polyethylene terephthalate film (Toyobo Ester (registered trademark) film, manufactured by TOYOBO MC Corporation)
OPET: biaxially stretched polyethylene terephthalate film (Teflex (registered trademark) film, manufactured by TOYOBO MC Corporation)
CPBT: non-stretched polybutylene terephthalate film (ESRM, manufactured by Okura Industrial Co., Ltd.)
Adhesive for lamination (TM593 (main agent), CAT-10L (curing agent), manufactured by Toyo Morton Ltd.) (solid content: 25% by mass, solvent: ethyl acetate)

### (3) Production of Mold Release Film

Each of the mold release films of Examples and Comparative Examples was produced as follows.

### Example 1

A mold release film was produced in a configuration shown in Table 1.

First, as an interlayer, the prepared melamine-based mold release layer (melamine; manufactured by Arakawa Chemical Industries, Ltd., ARACOAT, RL3021 (main agent)/RA2000 (curing agent)) (solid content: 10% by mass, solvent: IPA) prepared was applied onto a 25 μm-thick biaxially stretched polybutylene terephthalate film (OPBT) (BOBLET (registered trademark) ST, manufactured by KOHJIN Film & Chemicals Co., Ltd.) using a bar coater, and cured at 120° C. for 1 minute to produce a laminate including a mold release layer on the interlayer. Next, the obtained laminates were superimposed on each other such that the interlayers faced each other, and pressure-bonded using the adhesive (TM593 (main agent), CAT-10L (curing agent), manufactured by Toyo Morton Ltd. (solid content: 25% by mass, solvent: ethyl acetate)), and then subjected to an aging treatment at 50° C. for 48 hr to obtain a mold release film.

The thickness of each layer of the obtained mold release film is shown in Table 1. The thickness of the adhesive layer was 2 μm.

### Example 2

As shown in Table 1, a mold release film was produced in the same manner as in Example 1, except that each mold release layer was changed to the acrylic mold release agent (acrylic; manufactured by TOKUSHIKI CO., Ltd., SQ100 (main agent)/UAX-615 (curing agent)) (solid content: 10% by mass, solvent: ethyl acetate).

### Example 3

As shown in Table 1, a mold release film was produced in the same manner as in Example 1, except that each mold release layer was changed to the silicone-based mold release agent, a matte film was sandwiched after the coating using a bar coater, the laminate was cured at 120° C. for 1 minute, and the surface of the mold release layer was subjected to a roughening treatment.

### Example 4

As shown in Table 1, a mold release film was produced in the same manner as in Example 1, except that each interlayer was changed to the biaxially stretched polyethylene terephthalate film (Teflex (registered trademark) film, manufactured by TOYOBO MC Corporation) having a thickness of 13 μm.

### Example 5

As shown in Table 1, a mold release film was produced in the same manner as in Example 1, except that each interlayer was changed to a three-layer configuration (laminated in the order of OPET/CPBT/OPET) of the biaxially stretched polyethylene terephthalate film (Toyobo Ester (registered trademark) film, manufactured by TOYOBO MC Corporation) having a thickness of 9 μm and a non-stretched polyester film (ESRM, manufactured by Okura Industrial Co., Ltd.) having a thickness of 25 μm.

### Comparative Example 1

First, as shown in Table 1, a laminate was produced in the same manner as in Example 1, except that the interlayer 1 was changed to a non-stretched polyester film (ESRM, manufactured by Okura Industrial Co., Ltd.).

Next, the obtained laminate was superimposed on an interlayer 2 shown in Table 1 such that the interlayer 2 faced the interlayer 1 side, and then a mold release film was obtained in the same manner as in Example 1.

### Comparative Example 2

First, a laminate was produced in the same manner as in Example 1, except that, as shown in Table 1, the interlayer 1 was changed to the biaxially stretched polybutylene terephthalate film (BOBLET (registered trademark) ST, manufactured by KOHJIN Film & Chemicals Co., Ltd.).

Next, the obtained laminate was superimposed on an interlayer 2 (non-stretched polyester film (ESRM, manufactured by Okura Industrial Co., Ltd.)) shown in Table 1 such that the interlayer 2 faced the interlayer 1 side, and then a mold release film was obtained in the same manner as in Example 1.

### (4) Measurement of Physical Properties of Mold Release Film

Using the obtained mold release film, the following measurements and evaluations were performed. The results are shown in Table 1.

### (a) Tensile Stress of Mold Release Film

Using the obtained mold release film, a tensile stress (MPa) at 180° C. was measured according to JIS K 7127.

### (b) Surface Roughness Ra of Surface of Mold Release Film on Mold Release Layer Side

Measurement was performed according to JIS B 0601:2013.

### (5) Evaluation of Mold Release Film

Each mold release film was evaluated as follows. The results are shown in Table 1.

As a quick press-type device, HH46 LAMINATOR (quick press machine manufactured by TRM Co., Ltd.) was used, and the following evaluation was performed.

First, a copper-clad laminated plate for a flexible wiring board, on which an electrical wiring line having an L/S of 100/100 μm was formed, was prepared. In addition, a plurality of 1 mm square opening portions were produced in a coverlay (CMA0525) manufactured by Arisawa Mfg. Co., Ltd., and the surface of the coverlay, on which an adhesive had been coated, was attached to both surfaces of the copper-clad laminated plate for a flexible wiring board (width: 250 mm, length: 170 mm) to produce a temporarily fixed test piece.

Next, the evaluation was performed using the above-described quick press machine. At this time, the mold release film was disposed on both surfaces of the test piece such that the mold release surface of the mold release film on the first mold release layer side faced the test piece. Subsequently, a heat press treatment was performed for 1 minute under the conditions of 180° C., 2 MPa, and vacuum suction for 10 seconds to obtain a molded product,

### [Mold Releasability]

Mold releasability was evaluated based on mold releasing behavior in a case where the molded product was released from the mold release film after the heating press.
A: good in mold releasability and naturally released after pressing
B: sticking to the molded product occurred during the mold release, but it was easily released and there was no problem in practical use.
C; sticking to the molded product due to deformation of the film was strong, and it was difficult to release.

### [Adhesiveness]

In the above-described procedure, adhesiveness between the hot plate and the mold release film during the heating press was evaluated according to the following standard.
A: not attached to the hot plate and good in mold releasability
B: sticking to the hot plate occurred, but it was easily released and there was no problem in practical use.
C: film was strongly adhered to the hot plate due to the deformation of the film, and it was difficult to release the film from the hot plate.

### [Curling Property]

In the above-described procedure, the mold release film and curling behavior during the heating press were evaluated according to the following standard,
A: no curl was generated, and the molded product was closely adhered to the film.
B: minute curl was generated, and a curled portion of the film was bitten and embedded between the molded product and the film, but there was no practical problem in terms of adhesion.
C: curled portion of the film was bitten between the molded product and the film, which inhibited the adhesion between the molded product and the film.

TABLE 1

| | | | | | | | | Comparative | Comparative |
|---|---|---|---|---|---|---|---|---|---|
| | | Unit | Example 1 | Example 2 | Example 3 | Example 4 | Example 5 | Example 1 | Example 2 |
| First mold | Raw | — | Melamine- | Acrylic | Silicone- | Melamine- | Melamine- | Melamine- | Melamine- |
| release | material | | based | mold | based | based | based | based | based |
| layer | | | mold | release | mold | mold | mold | mold | mold |
| | | | release | agent | release | release | release | release | release |
| | | | agent | | agent | agent | agent | agent | agent |
| | Thickness | μm | 0.15 | 1 | 5 | 0.15 | 0.15 | 0.15 | 0.15 |
| | Surface | μm | 0.12 | 0.14 | 1.11 | 0.11 | 0.12 | 0.16 | 0.12 |
| | roughness | | | | | | | | |
| | Ra | | | | | | | | |
| Interlayer 1 | Raw | — | OPBT | OPBT | OPBT | OPBT | OPBT | OPBT | OPBT |
| | material | | | | | | | | |
| | Thickness | μm | 25 | 25 | 25 | 13 | 9 | 25 | 25 |
| Interlayer 2 | Raw | — | OPBT | OPBT | OPBT | OPBT | OPBT | OPBT | OPBT |
| | material | | | | | | | | |
| | Thickness | μm | 25 | 25 | 25 | 13 | 25 | 25 | 25 |
| Interlayer 3 | Raw | — | | | | | OPBT | | |
| | material | | | | | | | | |
| | Thickness | μm | | | | | 9 | | |
| Second mold | Raw | — | Melamine- | Acrylic | Silicone- | Melamine- | Melamine- | — | — |
| release | material | | based | mold | based | based | based | | |
| layer | | | mold | release | mold | mold | mold | | |
| | | | release | agent | release | release | release | | |
| | | | agent | | agent | agent | agent | | |
| | Thickness | μm | 0.15 | 1 | 5 | 0.15 | 0.15 | — | — |
| | Surface | μm | 0.11 | 0.15 | 0.36 | 0.11 | 0.10 | 0.18 | 0.15 |
| | roughness | | | | | | | | |
| | Ra | | | | | | | | |
| Physical | Tensile | MPa | 122 | 119 | 139 | 74 | 49 | 35 | 37 |
| properties | stress (MD) | | | | | | | | |

| | | | | | | | | |
|---|---|---|---|---|---|---|---|---|
| Evaluation | Mold | A | A | A | A | A | C | B |
| | releasability | | | | | | | |
| | Adhesiveness | A | A | A | A | A | C | C |
| | Curling property | A | A | A | A | A | A | C |

### 2. Examples According to Second Embodiment of Present Invention

### (1) Raw Materials of Mold Release Layer

Melamine-based mold release agent (melamine; manufactured by Arakawa Chemical Industries, Ltd., ARACOAT, RL3021 (main agent)/RA2000 (curing agent)) (solid content: 10% by mass, solvent: IPA)
Acrylic mold release agent (acrylic; manufactured by TOKUSHIKI CO., Ltd., SQ100 (main agent)/UAX-615 (curing agent)) (solid content: 10% by mass, solvent: ethyl acetate)
Silicone-based mold release agent (silicone; self-formulated) (solid content amount: 20% by mass, solvent: toluene)

### (2) Raw Materials of Interlayer

OPBT: biaxially stretched polybutylene terephthalate film (BOBLET (registered trademark) ST, manufactured by KOHJIN Film & Chemicals Co., Ltd.)
OPET: biaxially stretched polyethylene terephthalate film (Teflex (registered trademark) film, manufactured by TOYOBO MC Corporation)
CPBT: non-stretched polybutylene terephthalate film (ESRM, manufactured by Okura Industrial Co., Ltd.)
Adhesive for lamination (TM593 (main agent), CAT-10L (curing agent), manufactured by Toyo Morton Ltd.) (solid content: 25% by mass, solvent: ethyl acetate)

### (3) Production of Mold Release Film

Each of the mold release films of Examples and Comparative Examples was produced as follows.

### Example 1

A mold release film was produced in a configuration shown in Table 2.

First, as an interlayer, the prepared melamine-based mold release layer (melamine; manufactured by Arakawa Chemical Industries, Ltd., ARACOAT, RL3021 (main agent)/RA2000 (curing agent)) (solid content: 10% by mass, solvent: IPA) prepared was applied onto a 25 μm-thick biaxially stretched polybutylene terephthalate film (OPBT) (BOBLET (registered trademark) ST, manufactured by KOHJIN Film & Chemicals Co., Ltd.) using a bar coater, and cured at 120° C. for 1 minute to produce a laminate including a mold release layer on the interlayer. Next, the obtained laminates were superimposed on each other such that the interlayers faced each other, and pressure-bonded using the adhesive (TM593 (main agent), CAT-10L (curing agent), manufactured by Toyo Morton Ltd. (solid content: 25% by mass, solvent: ethyl acetate)), and then subjected to an aging treatment at 50° C. for 48 hr to obtain a mold release film.

The thickness of each layer of the obtained mold release film is shown in Table 2. The thickness of the adhesive layer was 2 μm.

### Example 2

As shown in Table 2, a mold release film was produced in the same manner as in Example 1, except that each mold release layer was changed to the acrylic mold release agent (acrylic; manufactured by TOKUSHIKI CO., Ltd., SQ100 (main agent)/UAX-615 (curing agent)) (solid content: 10% by mass, solvent: ethyl acetate).

### Example 3

As shown in Table 2, a mold release film was produced in the same manner as in Example 1, except that each mold release layer was changed to the silicone-based mold release agent, a matte film was sandwiched after the coating using a bar coater, the laminate was cured at 120° C. for 1 minute, and the surface of the mold release layer was subjected to a roughening treatment.

### Example 4

As shown in Table 2, a mold release film was produced in the same manner as in Example 1, except that each interlayer was changed to the biaxially stretched polyethylene terephthalate film (Teflex (registered trademark) film, manufactured by TOYOBO MC Corporation) having a thickness of 13 μm.

### Comparative Example 1

First, as shown in Table 2, a laminate was produced in the same manner as in Example 1, except that the interlayer 1 was changed to a non-stretched polyester film (ESRM, manufactured by Okura Industrial Co., Ltd.).

Next, the obtained laminate was superimposed on an interlayer 2 shown in Table 2 such that the interlayer 2 faced the interlayer 1 side, and then a mold release film was obtained in the same manner as in Example 1.

### Comparative Example 2

First, a laminate was produced in the same manner as in Example 1, except that, as shown in Table 2, the interlayer 1 was changed to the biaxially stretched polybutylene terephthalate film (BOBLET (registered trademark) ST, manufactured by KOHJIN Film & Chemicals Co., Ltd.).

Next, the obtained laminate was superimposed on an interlayer 2 (non-stretched polyester film (ESRM, manufactured by Okura Industrial Co., Ltd.)) shown in Table 2 such that the interlayer 2 faced the interlayer 1 side, and then a mold release film was obtained in the same manner as in Example 1.

### (4) Measurement of Physical Properties of Mold Release Film

Using the obtained mold release film, the following measurements and evaluations were performed. The results are shown in Table 2.

### (a) Tensile Stress of Mold Release Film

Using the obtained mold release film, a tensile stress (MPa) at 180° C. was measured according to JIS K 7127.

### (b) Surface Roughness Ra of Surface of Mold Release Film on Mold Release Layer Side

Measurement was performed according to JIS B 0601:2013.

### (c) Thermal Dimensional Change Rate (%)

By thermo-mechanical analysis (“TMA7100” manufactured by Hitachi High-Tech Science Corporation), a thermal dimensional change rate (%) in a case where the temperature was raised from 30° C. to 180° C. at 2° C./min with a tensile load of 500 mN was measured.

### (d) Storage Elasticity Rate

According to JIS K 7244:1998, a dynamic viscoelasticity (DMA) was measured at a temperature rising rate of 5° C./min and a frequency of 1 Hz.

### (e) Measurement of Surface Free Energy

The measurement was performed by Owens-Wendt method. Specifically, contact angles of 10 liquid droplets of water, diiodomethane, and hexadecane were measured using a solid-liquid interface analysis apparatus (manufactured by Kyowa Interface Science Co., Ltd., “DM-501”), and the average value thereof was obtained.

### (6) Evaluation of Mold Release Film

Each mold release film was evaluated as follows. The results are shown in Table 2.

As a quick press-type device, HH46 LAMINATOR (quick press machine manufactured by TRM Co., Ltd.) was used, and the following evaluation was performed.

First, a copper-clad laminated plate for a flexible wiring board, on which an electrical wiring line having an L/S of 100/100 μm was formed, was prepared. In addition, a plurality of 1 mm square opening portions were produced in a coverlay (CMA0525) manufactured by Arisawa Mfg. Co., Ltd., and the surface of the coverlay, on which an adhesive had been coated, was attached to both surfaces of the copper-clad laminated plate for a flexible wiring board (width: 250 mm, length: 170 mm) to produce a temporarily fixed test piece.

Next, the evaluation was performed using the above-described quick press machine. At this time, the mold release film was disposed on both surfaces of the test piece such that the mold release surface of the mold release film on the first mold release layer side faced the test piece. Subsequently, a heat press treatment was performed for 1 minute under the conditions of 180° C., 2 MPa, and vacuum suction for 10 seconds to obtain a molded product.

### [Mold Releasability]

Mold releasability was evaluated based on mold releasing behavior in a case where the molded product was released from the mold release film after the heating press,
A: good in mold releasability and naturally released after pressing
B: sticking to the molded product occurred during the mold release, but it was easily released and there was no problem in practical use.
C: sticking to the molded product due to deformation of the film was strong, and it was difficult to release.

### [Adhesiveness]

In the above-described procedure, adhesiveness between the hot plate and the mold release film during the heating press was evaluated according to the following standard.
A: not attached to the hot plate and good in mold releasability
B: sticking to the hot plate occurred, but it was easily released and there was no problem in practical use.
C: film was strongly adhered to the hot plate due to the deformation of the film, and it was difficult to release the film from the hot plate.

### [Curling Property]

In the above-described procedure, the mold release film and curling behavior during the heating press were evaluated according to the following standard,
A: no curl was generated, and the molded product was closely adhered to the film.
B: minute curl was generated, and a curled portion of the film was bitten and embedded between the molded product and the film, but there was no practical problem in terms of adhesion.
C: curled portion of the film was bitten between the molded product and the film, which inhibited the adhesion between the molded product and the film.

TABLE 2

| | | | | | | | Comparative | Comparative |
|---|---|---|---|---|---|---|---|---|
| | | Unit | Example 1 | Example 2 | Example 3 | Example 4 | Example 1 | Example 2 |
| First mold | Raw material | — | Melamine- | Acrylic | Silicone- | Melamine- | Melamine- | Melamine- |
| release | | | based | mold | based | based | based | based |
| layer | | | mold | release | mold | mold | mold | mold |
| | | | release | agent | release | release | release | release |
| | | | agent | | agent | agent | agent | agent |
| | Thickness | μm | 0.15 | 1 | 5 | 0.15 | 0.1 | 0.15 |
| | Surface free | mJ/m² | 24.2 | 23.2 | 16.0 | 23.2 | 26.2 | 23.9 |
| | energy SC1 | | | | | | | |
| Interlayer 1 | Resin | — | OPBT | OPBT | OPBT | OPBT | OPBT | OPBT |
| | composition | | | | | | | |
| | Thickness | μm | 25 | 25 | 25 | 13 | 25 | 25 |
| Interlayer 2 | Resin | — | OPBT | OPBT | OPBT | OPBT | OPBT | OPBT |
| | composition | | | | | | | |
| | Thickness | μm | 25 | 25 | 25 | 13 | 25 | 25 |
| Second mold | Raw material | — | Melamine- | Acrylic | Silicone- | Melamine- | — | — |
| release | | | based | mold | based | based | | |
| layer | | | mold | release | mold | mold | | |
| | | | release | agent | release | release | | |
| | | | agent | | agent | agent | | |
| | Thickness | μm | 0.15 | 1 | 5 | 0.15 | — | — |
| | Surface free | mJ/m² | 23.3 | 24.8 | 15.6 | 23.1 | 43.1 | 36.7 |
| | energy SC2 | | | | | | | |
| Physical | Storage elastic | MPa | 285 | 329 | 305 | 239 | 137 | 123 |
| properties | modulus (180° C.) | | | | | | | |
| | Storage elastic | MPa | 906 | 1230 | 991 | 2340 | 322 | 433 |
| | modulus (100° C.) | | | | | | | |
| | ε′ (180) · | MPa | 621 | 901 | 686 | 2101 | 185 | 310 |
| | ε′ (100) | | | | | | | |
| | Thermal | % | 3.2 | 2.9 | 1.7 | 7.6 | >55 | 9.1 |
| | dimensional | | | | | | | |
| | change | | | | | | | |
| | rate (MD) | | | | | | | |
| | Tensile | MPa | 122 | 119 | 139 | 74 | 35 | 37 |
| | stress (MD) | | | | | | | |

| | | | | | | | |
|---|---|---|---|---|---|---|---|
| Evaluation | Mold releasability | A | A | A | A | C | B |
| | Adhesiveness | A | A | A | A | C | C |
| | Curling property | A | A | A | A | A | C |

### 3. Examples According to Third Embodiment of Present Invention

### (1) Raw Materials of Mold Release Layer

Melamine-based mold release agent: manufactured by Arakawa Chemical Industries, Ltd., ARACOAT, RL3021 (main agent)/RA2000 (curing agent)) (solid content: 10% by mass, solvent: IPA)
Acrylic mold release agent: manufactured by TOKUSHIKI CO., Ltd., SQ100 (main agent)/UAX-615 (curing agent)) (solid content: 10% by mass, solvent: ethyl acetate)
Silicone-based mold release agent: self-formulated (solid content amount: 20% by mass, solvent: toluene)

### (2) Raw Materials of Interlayer

OPBT-1: biaxially stretched polybutylene terephthalate film (BOBLET (registered trademark) ST, manufactured by KOHJIN Film & Chemicals Co., Ltd.)
OPBT-2: biaxially stretched polybutylene terephthalate film (Tafstar (registered trademark) ST, manufactured by TOYOBO MC Corporation)
OPET-1: biaxially stretched polyethylene terephthalate film (Toyobo Ester (registered trademark) film, manufactured by TOYOBO MC Corporation)
OPET-2: biaxially stretched polyethylene terephthalate film (Tiafine (registered trademark) film, manufactured by TOYOBO MC Corporation, containing a polyester copolymer other than polyethylene terephthalate)
OPET-3: biaxially stretched polyethylene terephthalate film (Teflex (registered trademark) film, manufactured by TOYOBO MC Corporation)
OPET-4: biaxially stretched polyethylene terephthalate film (LUMIRROR (registered trademark) film, manufactured by TORAY INDUSTRIES, INC.)
CPBT: non-stretched polybutylene terephthalate film (ESRM, manufactured by Okura Industrial Co., Ltd.)
Adhesive for lamination: TM593 (main agent), CAT-10L (curing agent), manufactured by Toyo Morton Ltd. (solid content: 25% by mass, solvent: ethyl acetate)

### (3) Production of Mold Release Film

Each of the mold release films of Examples and Comparative Examples was produced as follows.

### Example 1

A mold release film was produced in a configuration shown in Table 3.

First, as an interlayer a, the melamine-based mold release agent prepared as a raw material for a mold release layer was applied onto OPET-1 (having a thickness of 12 μm) using a bar coater, and cured at 120° C. for 1 minute to produce a laminate including the mold release layer on the interlayer a. Next, a laminating adhesive was applied onto a back surface (surface on the interlayer a side) of two obtained laminates, and the two laminates were superimposed on each other with OPBT-2 (having a thickness of 20 μm) interposed therebetween as an interlayer b, and were pressure-bonded. Thereafter, an aging treatment at 50° C. for 48 hr was performed, and the produced mold release film was subjected to a heating and pressurizing treatment using an offline embossing device to obtain a mold release film.

The thickness of each layer of the obtained mold release film is shown in Table 3. The thickness of the adhesive layer was approximately 2 μm.

### Example 2

As shown in Table 3, a mold release film was produced in the same manner as in Example 1, except that the melamine-based mold release agent of the mold release layer was changed to the acrylic mold release agent.

### Example 3

As shown in Table 3, a mold release film was produced in the same manner as in Example 1, except that OPET-1 (having a thickness of 12 μm) of the interlayer a was changed to OPBT-1 (having a thickness of 15 μm), and OPBT-2 of the interlayer b was changed to OPET-1 (having a thickness of 12 μm).

### Example 4

As shown in Table 3, a mold release film was produced in the same manner as in Example 1, except that OPBT-2 (having a thickness of 20 μm) of the interlayer b was changed to OPET-2 (having a thickness of 13 μm).

### Example 5

As shown in Table 3, a mold release film was produced in the same manner as in Example 1, except that OPBT-2 (having a thickness of 20 μm) of the interlayer b was changed to OPET-3 (having a thickness of 14 μm).

### Example 6

As shown in Table 3, a mold release film was produced in the same manner as in Example 1, except that OPBT-2 (having a thickness of 20 μm) of the interlayer b was changed to OPET-2 (having a thickness of 13 μm), and the melamine-based mold release agent as the mold release layer was changed to the silicone-based mold release agent.

### Comparative Example 1

A mold release film was produced in a configuration shown in Table 3.

First, as shown in Table 3, as an interlayer a, the melamine-based mold release agent adjusted as a raw material for a mold release layer was applied onto OPBT-1 (having a thickness of 25 μm) using a bar coater, and cured at 120° C. for 1 minute to produce a laminate including the mold release layer on the interlayer a. Next, CPBT (having a thickness of 25 μm) was laminated on the surface of the obtained laminate on the interlayer a side as an interlayer b. Thereafter, the aging treatment and the heating and pressurizing treatment were performed in the same manner as in Example 1 to obtain a mold release film.

### (4) Measurement of Various Physical Properties

Using the obtained mold release film and the like, the following measurements and evaluations were performed. The results are shown in Table 3.
Measurement of thermal dimensional change rate

### (Procedure a)

The obtained mold release film was subjected to thermal analysis in a state of being applied with a load of 10 mN using a thermo-mechanical analyzer (TMA7100 (manufactured by Hitachi High-Tech Science Corporation)) at a temperature rising rate of 5° C./min from 20° C. to 210° C., and thermal dimensional change rates A of the mold release film at 180° C. were measured in each of the ID direction and the MD direction.

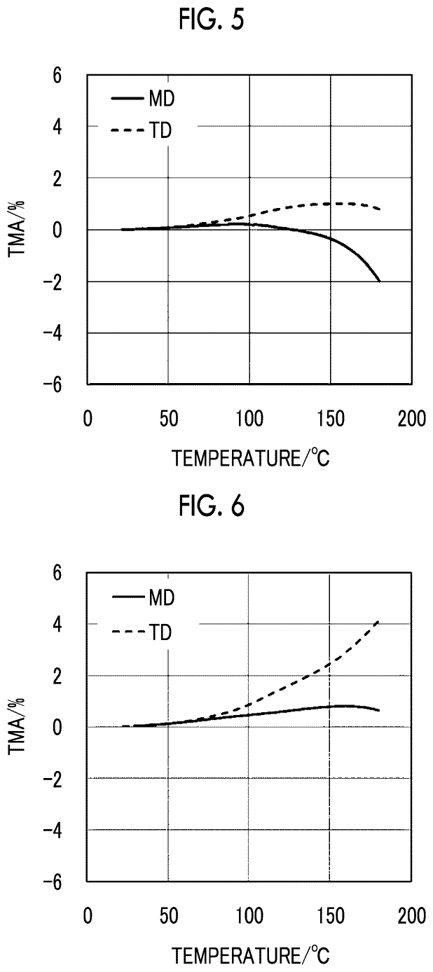

FIG. 5 shows the TMA measurement results of the mold release film of Example 1 according to the procedure a.

### (Procedure b)

The obtained mold release film was subjected to thermal analysis in a state of being applied with a load of 500 mN using a thermo-mechanical analyzer (TMA7100 (manufactured by Hitachi High-Tech Science Corporation)) at a temperature rising rate of 5° C./min from 20° C. co 210° C., and thermal dimensional change rates B of the mold release film at 180° C. were measured in each of the TD direction and the MD direction.

FIG. 6 shows the TMA measurement results of the mold release film of Example 1 according to the procedure b.

### (5) Evaluation of Mold Release Film

Using the obtained mold release film, the following evaluations were performed. The results are shown in Table 3.

### [Mold Followability]

In the above-described procedure, the degree of air pockets between the mold and the mold release film in a case where the mold release film was followed by the mold by the vacuum suction was evaluated according to the following standard.
A: no air pocket was generated.
B: there were minute air pockets, but there was no problem in practice.
C: there were minute air pockets, which reduced vacuum degree for film adsorption.
D: large air pocket and occurrence of following failure (or evaluation impossible)

### [Mold Releasability]

In the above-described procedure, mold releasing behavior in a case where the cured product was released from the mold release film after molding, and the state (shift, deflection, and the like) of the cured product were evaluated according to the following standard.
A: mold releasability and molded product were both satisfactory.
B: mold product was displaced or bent during the releasing, but there was no problem in practical use.
C: it was impossible to release the mold, or a large shift or deflection of the molded product occurred.

### [Moldability]

In the above-described procedure, the appearance state (wrinkles and the like) of the cured product after the molded product was released from the mold release film after molding was evaluated according to the following standard.
A: no problem with respect to wrinkles and deformation
B: slight wrinkles were present, but there was no problem in practical use.
C: large wrinkles were generated and transferred.

### [Curling Property]

In the above-described procedure, the mold release film and curling behavior during the heat pressing were evaluated according to the following standard.
A: no curl was generated, and the test piece was closely adhered to the film.
B: minute curl was generated, and a curled portion of the mold release film was bitten and embedded between the test piece and the mold release film, but there was no practical problem in terms of adhesion.
C: curled portion of the mold release film was bitten between the test piece and the mold release film, which inhibited the adhesion between the test piece and the mold release film.

TABLE 3

| | | | | | | | | | Comparative |
|---|---|---|---|---|---|---|---|---|---|
| | | Unit | Example 1 | Example 2 | Example 3 | Example 4 | Example 5 | Example 6 | Example 1 |
| First mold | Raw material | — | Melamine- | Acrylic | Melamine- | Melamine- | Melamine- | Silicone- | Melamine- |
| release | | | based | mold | based | based | based | based | based |
| layer | | | mold | release | mold | mold | mold | mold | mold |
| | | | release | agent | release | release | release | release | release |
| | | | agent | | agent | agent | agent | agent | agent |
| | Thickness | μm | 0.15 | 0.15 | 0.15 | 0.15 | 0.15 | 5 | 0.15 |
| Interlayer a | Raw material | — | OPBT-1 | OPBT-1 | OPBT-1 | OPBT-1 | OPBT-1 | OPBT-1 | OPBT-1 |
| | Thickness | μm | 12 | 12 | 15 | 12 | 12 | 12 | 25 |
| Interlayer b | Raw material | — | OPBT-2 | OPBT-2 | OPBT-1 | OPBT-2 | OPBT-3 | OPBT-2 | OPBT |
| | Thickness | μm | 20 | 20 | 12 | 13 | 14 | 13 | 25 |
| Interlayer a | Raw material | — | OPBT-1 | OPBT-1 | OPBT-1 | OPBT-1 | OPBT-1 | OPBT-1 | — |
| | Thickness | μm | 12 | 12 | 15 | 12 | 12 | 12 | — |
| Second mold | Raw material | — | Melamine- | Acrylic | Melamine- | Melamine- | Melamine- | Silicone- | — |
| release | | | based | mold | based | based | based | based | |
| layer | | | mold | release | mold | mold | mold | mold | |
| | | | release | agent | release | release | release | release | |
| | | | agent | | agent | agent | agent | agent | |
| | Thickness | μm | 0.15 | 0.15 | 0.15 | 5 | 5 | 5 | — |
| Physical | Thermal | % | 0.8 | 1.0 | 0.9 | 0.4 | 0.9 | 1.5 | 3.4 |
| properties | dimensional | | | | | | | | |
| | change rate At | | | | | | | | |
| | Thermal | % | −2.0 | −3.3 | −3.2 | −3.6 | −2.5 | −2.4 | −2.2 |
| | dimensional | | | | | | | | |
| | change rate Am | | | | | | | | |
| | Thermal | % | 4.1 | 4.9 | 4.7 | 4.0 | 3.3 | 4.5 | 13 |
| | dimensional | | | | | | | | |
| | change rate Bt | | | | | | | | |
| | Thermal | % | 0.7 | 0.3 | 0.2 | 0.5 | 0.4 | 1.1 | 9 |
| | dimensional | | | | | | | | |
| | change rate Bm | | | | | | | | |
| | At − Am | % | 2.8 | 4.3 | 4.1 | 4 | 3.7 | 3.9 | −5.6 |
| Evaluation | Mold | — | B | B | B | B | B | B | A |
| | followability | | | | | | | | |
| | Mold | — | B | B | B | B | B | B | B |
| | releasability | | | | | | | | |
| | Adhesiveness | — | B | B | B | B | B | B | D |
| | Curling | — | B | B | B | B | B | B | D |
| | property | | | | | | | | |

This application claims priority based on Japanese Patent Application No. 2022-001549 filed on Jan. 7, 2022, Japanese Patent Application No. 2022-001551 filed on Jan. 7, 2022, Japanese Patent Application No. 2022-171349 filed on Oct. 26, 2022, and Japanese Patent Application No. 2022-186862 filed on Nov. 22, 2022, all of its disclosures are incorporated herein.

### REFERENCE SIGNS LIST

11 first mold release layer
12 second mold release layer
20 interlayer
20a interlayer
20b interlayer
100 mold release film
200 mold release film
300 mold release film

1. A mold release film comprising:
a first mold release layer constituting one mold release surface;
an interlayer; and
a second mold release layer constituting the other mold release surface,
wherein the first mold release layer, the interlayer, and the second mold release layer are laminated in this order, and
wherein the interlayer is composed of a resin composition for the interlayer, containing a polyester resin.

2. A mold release film comprising:
a first mold release layer over at least one surface,
wherein, in a case where a surface free energy of the one surface of the mold release film
is denoted by SC1 and a surface free energy of the other surface of the mold release film is denoted by SC2, SC1 is 15 to 35 [mJ/m²] and |SC1-SC2| is less than 2.0.

3. The mold release film according to claim 2,
wherein a thermal dimensional change rate at 180° C. in an MD direction, which is measured by a thermomechanical analysis (TMA) method, is equal to or less than 9%.

4. The mold release film according to claim 2,
wherein, in a case where a storage elastic modulus of the mold release film at 180° C., which is measured using a dynamic viscoelasticity measuring device (tensile mode, a frequency of 1 Hz, and a temperature rising rate of 5° C./min), is denoted by E′ (180) [MPa] and a storage elastic modulus of the mold release film at 100° C. is denoted by E′ (100) [MPa], E′ (100)-E′ (180) is equal to or more than 350 [MPa].

5. The mold release film according to claim 2, further comprising:
an interlayer over a surface of the first mold release layer opposite to a mold release surface side,
wherein the interlayer is composed of a resin composition for the interlayer, containing a polyester resin.

6. The mold release film according to claim 2, further comprising:
a second mold release layer over the other surface.

7. The mold release film according to claim 1,
wherein the mold release film has a symmetrical structure and/or a symmetrical composition with respect to a center plane in a direction perpendicular to a thickness direction of the mold release film.

8. The mold release film according to claim 1,
wherein a tensile stress of the mold release film in an MD direction, which is obtained in a case where a tensile test is performed according to JIS K 7127 under conditions of 180° C. and a load rate of 500 mm/min, is equal to or more than 40 MPa.

9. The mold release film according to claim 1,
wherein the polyester resin includes one kind or two or more kinds selected from a polyethylene terephthalate resin (PET), a polyethylene terephthalate glycol resin (PETG), a polybutylene terephthalate resin (PBT), a polytrimethylene terephthalate resin (PTT), a polyhexamethylene terephthalate resin (PHT), and a copolymerized polyethylene terephthalate/isophthalate resin (PET/PEI).

10. The mold release film according to claim 1,
wherein the first mold release layer and the second mold release layer are each composed of a resin composition for a mold release layer, containing one kind or two or more kinds selected from a silicone resin, a fluororesin, a melamine resin, an epoxy resin, a phenol resin, and an acrylic resin.

11. The mold release film according to claim 1,
wherein a thickness of the interlayer is 20 to 100 μm.

12. The mold release film according to claim 1,
wherein the interlayer is obtained by laminating a plurality of films formed of the resin composition for the interlayer.

13. The mold release film according to claim 12,
wherein the interlayer is obtained by laminating the plurality of films through an adhesive layer.

14. The mold release film according to claim 13,
wherein the adhesive layer is composed of one kind or two or more kinds selected from polyester, polyether, polyisocyanate, and polyurethane.

15. The mold release film according to claim 13,
wherein a thickness of the adhesive layer is 0.5 to 10 μm.

16. The mold release film according to claim 1,
wherein the interlayer includes a stretched film formed of the resin composition for the interlayer.

17-31. (canceled)
